(19) United States
(12) Patent Application Publication
(10) Pub. No.: US 2026/0262290 A1
(43) Pub. Date: Sep. 3, 2026

(54) DISPLAY SUBSTRATE AND PREPARATION METHOD THEREFOR, AND DISPLAY APPARATUS

(71) Applicants: Hefei Xinsheng Optoelectronics Technology Co., Ltd., Hefei (CN); BOE Technology Group Co., Ltd., Beijing (CN)

(72) Inventors: Ning LIU, Beijing (CN); Dacheng ZHANG, Beijing (CN); Jun GENG, Beijing (CN); Feng ZHANG, Beijing (CN); Yang PAN, Beijing (CN); Bin ZHOU, Beijing (CN); Liangchen YAN, Beijing (CN)

(21) Appl. No.: 19/656,961

(22) Filed: Apr. 23, 2026

Related U.S. Application Data
(63) Continuation of application No. 17/770,045, filed on Jul. 20, 2021.

(30) Foreign Application Priority Data
Jul. 23, 2020 (CN) 202010719363.6

(51) Int. Cl. H10D 86/40; H10K 59/121; H10K 59/131; H10K 59/12; H10K 102/00

(52) U.S. Cl. CPC H10D 86/423; H10K 59/1213; H10K 59/1216; H10K 59/131; H10K 59/1201; H10K 2102/00

(57) ABSTRACT

A display substrate includes a first metal layer, a first insulating layer, a metal oxide layer, a second insulating layer and a second metal layer which are stacked on a substrate base. The metal oxide layer includes a first active layer, and the second metal layer includes a first gate electrode, a first source electrode, and a first drain electrode. The first active layer includes a channel region, a source transition region and a drain transition region located at two sides of the channel region, a source connection region located at a side of the source transition region away from the channel region and a drain connection region located at a side of the drain transition region away from the channel region.

### CROSS-REFERENCE TO RELATED APPLICATIONS

This application is a continuation of U.S. Patent Application No. 17/770,045 filed on April 18, 2022, which is a national stage application of PCT Application No. PCT/CN2021/107419, which is filed on July 20, 2021 and claims priority of Chinese Patent Application No. 202010719363.6 filed to the CNIPA on July 23, 2020, entitled “Display Substrate and Preparation Method Therefor, and Display Apparatus”. The above-identified applications are incorporated by reference herein in their entirety.

### TECHNICAL FIELD

Exemplary embodiments of the present disclosure relate to, but are not limited to, the field of display technology, and in particular to a display substrate, a preparation method therefor, and a display apparatus.

### BACKGROUND

Organic Light Emitting Diode (OLED) display apparatuses have the advantages such as ultra-thinness, large angle of view, active light emitting, high brightness, continuous and adjustable light emitting color, low cost, fast response, low power consumption, wide operating temperature range and flexible display, and have gradually become a promising next generation display technology. According to different driving modes, OLEDs may be divided into two types, i.e., a passive matrix (PM) driving type and an active matrix (AM) driving type. The AM OLED is a current-driven device which uses an independent thin film transistor (TFT for short) to control each sub-pixel, each sub-pixel may be continuously and independently driven to emit light. According to different light emitting directions, the OLED may be divided into a top-emitting type OLED and a bottom-emitting type OLED, and the bottom-emitting OLED is an earliest used structure.

In OLED design, a pixel aperture ratio is one of important parameters, and it is also an important factor to improve a resolution of the display apparatus, for example, especially for the bottom-emitting type OLED. In order to ensure capacity of a storage capacitor, an electrode plate of the storage capacitor needs a large area. With the development of high-resolution (PPI) display technology, a size of the sub-pixel is getting increasingly smaller, which makes a region of a driving circuit occupy a larger and larger proportion of pixel area, resulting in a significant reduction in the pixel aperture ratio.

### SUMMARY

The following is a summary of subject matters described in detail herein. The summary is not intended to limit the scope of protection of claims.

A display substrate including a first metal layer, a first insulating layer, a metal oxide layer, a second insulating layer and a second metal layer which are stacked on a substrate base; wherein the metal oxide layer includes a first active layer, and the second metal layer includes a first gate electrode, a first source electrode, and a first drain electrode; the first active layer includes a channel region, a source transition region and a drain transition region located at two sides of the channel region, a source connection region located at a side of the source transition region away from the channel region and a drain connection region located at a side of the drain transition region away from the channel region; the source connection region is connected with the first source electrode, and the drain connection region is connected with the first drain electrode; the source transition region and the drain transition region each include a first region away from the channel region and a second region close to the channel region; a conductivity of the first active layer corresponding to the first region is higher than a conductivity of the first active layer corresponding to the second region, or oxygen content of the first active layer corresponding to the first region is less than oxygen content of the first active layer corresponding to the second region, or a thickness of the first active layer corresponding to the first region is less than a thickness of the first active layer corresponding to the second region.

In an exemplary implementation, the conductivity of the first active layer corresponding to the first region is higher than a conductivity of the first active layer corresponding to the source connection region and the drain connection region, or the oxygen content of the first active layer corresponding to the first region is less than oxygen content of the first active layer corresponding to the source connection region and the drain connection region, or the thickness of the first active layer corresponding to the first region is less than a thickness of the first active layer corresponding to the source connection region and the drain connection region.

In an exemplary implementation, a width of the first region is less than a width of the source connection region, or the width of the first region is less than a width of the drain connection region.

In an exemplary implementation, a width of the first region is less than a width of the second region.

In an exemplary implementation, a width of the first region is less than a width of the channel region.

In an exemplary implementation, an orthographic projection of at least portion of the first region in the source transition region on the substrate base does not overlap with an orthographic projection of the first metal layer on the substrate base, or an orthographic projection of at least portion of the first region in the drain transition region on the substrate base does not overlap with the orthographic projection of the first metal layer on the substrate base.

In an exemplary implementation, the first active layer further includes a source outside region located at a side of the source connection region away from the channel region and a drain outside region located at a side of the drain connection region away from the channel region.

In an exemplary implementation, a width of the first region is less than a width of the source outside region, or the width of the first region is less than a width of the drain outside region.

In an exemplary implementation, a width of the second region is greater than a width of the source outside region, or the width of the second region is greater than a width of the drain outside region.

In an exemplary implementation, a width of the source outside region is less than a width of the source connection region, or a width of the drain outside region is less than a width of the drain connection region.

In an exemplary implementation, a boundary of an orthographic projection of the first gate electrode on the substrate base is located within a boundary range of an orthographic projection of the second insulating layer on the substrate base, and a boundary of an orthographic projection of the channel region on the substrate base is located within the range boundary of the orthographic projection of the second insulating layer on the substrate base.

In an exemplary implementation, the display substrate includes multiple sub-pixels arranged regularly, each sub-pixel includes a pixel driving circuit and an organic electroluminescent diode electrically connected with the pixel driving circuit, the pixel driving circuit includes a storage capacitor including a first electrode plate and a second electrode plate, and an orthographic projection of the first electrode plate on the substrate base and an orthographic projection of the second electrode plate on the substrate base have an overlapping region.

In an exemplary implementation, the pixel driving circuit further includes a first transistor, a second transistor, and a third transistor; a gate electrode of the first transistor is coupled to a second electrode of the second transistor, a first electrode of the first transistor is coupled to a first power supply line, a second electrode of the first transistor is coupled to a first electrode of the organic electroluminescent diode, and a second electrode of the organic electroluminescent diode is coupled to a second power supply line; a gate electrode of the second transistor is coupled to a first scan line, and a first electrode of the second transistor is coupled to a data line; a gate electrode of the third transistor is coupled to a second scan line, a first electrode of the third transistor is coupled to a compensation line, and a second electrode of the third transistor is coupled to the second electrode of the first transistor; and a first electrode of the storage capacitor is coupled to the gate electrode of the first transistor, and a second electrode of the storage capacitor is coupled to the second electrode of the first transistor.

In an exemplary implementation, the display substrate further includes a first conductive layer, the first conductive layer includes the first electrode plate of the storage capacitor, and the metal oxide layer includes the second electrode plate of the storage capacitor.

In an exemplary implementation, a material of the first electrode plate includes a transparent conductive material, and the overlapping region is located in a light emitting region of the display substrate.

In an exemplary implementation, the first metal layer includes the first electrode plate of the storage capacitor and the metal oxide layer includes the second electrode plate of the storage capacitor.

In an exemplary implementation, the second metal layer includes the first electrode plate of the storage capacitor and the metal oxide layer includes the second electrode plate of the storage capacitor.

In an exemplary implementation, the first metal layer includes the first electrode plate of the storage capacitor and the second metal layer includes the second electrode plate of the storage capacitor.

In an exemplary implementation, a conductivity of the metal oxide layer corresponding to the second electrode plate is higher than the conductivity of the first active layer corresponding to the second region, or oxygen content of the metal oxide layer corresponding to the second electrode plate is less than the oxygen content of the first active layer corresponding to the second region, or a thickness of the metal oxide layer corresponding to the second electrode plate is less than the thickness of the first active layer corresponding to the second region.

In an exemplary implementation, the first metal layer includes the first power supply line and a first connection electrode connected with the first electrode plate, and a transparent conductive thin film is disposed between the first metal layer and the substrate base; and an orthographic projection of the first connection electrode on the substrate base and the orthographic projection of the channel region of the first active layer on the substrate base have an overlapping region.

In an exemplary implementation, the first source electrode and the first drain electrode are disposed on the first insulating layer; the first drain electrode is erected on the drain connection region of the first active layer and is connected with the first connection electrode through a first via; and a first end of the first source electrode is connected with the first power supply line through a second via, and a second end of the first source electrode is erected on the source connection region of the first active layer.

In an exemplary implementation, the first source electrode and the first drain electrode are disposed on the second insulating layer; the first drain electrode is connected with the drain connection region of the first active layer through a first active via and is connected with the first connection electrode through the first via; and a first end of the first source electrode is connected with the first power supply line through a second via, and a second end of the first source electrode is connected with the source connection region of the first active layer through a second active via.

A display apparatus, including the above display substrate.

A preparation method for a display substrate, including:

forming a first metal layer and a metal oxide layer on a substrate base sequentially, wherein the metal oxide layer includes a first active layer; and

forming a second insulating layer and a second metal layer sequentially, and forming, by performing two conductorization treatments, a channel region, a source transition region and a drain transition region located at two sides of the channel region, a source connection region located at a side of the source transition region away from the channel region and a drain connection region located at a side of the drain transition region away from the channel region in the first active layer; wherein the second metal layer includes a first gate electrode, a first source electrode, and a first drain electrode, the source connection region is connected with the first source electrode, and the drain connection region is connected with the first drain electrode; the source transition region and the drain transition region each include a first region away from the channel region and a second region close to the channel region; and a conductivity of the first active layer corresponding to the first region is higher than a conductivity of the first active layer corresponding to the second region, or oxygen content of the first active layer corresponding to the first region is less than oxygen content of the first active layer corresponding to the second region, or a thickness of the first active layer corresponding to the first region is less than a thickness of the first active layer corresponding to the second region.

In an exemplary implementation, the forming the first metal layer and the metal oxide layer on the substrate base sequentially includes:

forming a transparent first electrode plate and the first metal layer on the substrate base, wherein a transparent conductive thin film is disposed between the first metal layer and the substrate base; the first metal layer includes a first power supply line and a first connection electrode, the first connection electrode is connected with the first electrode plate;

forming a first insulating layer covering the first electrode plate and the first metal layer; and

forming the metal oxide layer on the first insulating layer; wherein the metal oxide layer includes the first active layer and a second electrode plate, an orthographic projection of the second electrode plate on the substrate base and an orthographic projection of the first electrode plate on the substrate base have an overlapping region, and an orthographic projection of the channel region of the first active layer on the substrate base and an orthographic projection of the first connection electrode on the substrate base have an overlapping region.

In an exemplary implementation, forming the second insulating layer and the second metal layer sequentially, and forming, by performing the two conductorization treatment, the channel region, the source transition region and the drain transition region located at two sides of the channel region, the source connection region located at the side of the source transition region away from the channel region and the drain connection region located at the side of the drain transition region away from the channel region in the first active layer, includes:

forming a second insulating layer on the first active layer, and forming a first via and a second via on the first insulating layer; wherein the second insulating layer covers a middle region of the first active layer; the first via and the second via respectively expose the first connection electrode and the first power supply line;

performing a first conductorization treatment on the second electrode plate and two side regions of the first active layer not covered by the second insulating layer, to form the second electrode plate conductorized, and forming the source connection region and the drain connection region at two sides of the first active layer respectively;

forming a second metal layer and retaining a photoresist on the second metal layer; wherein the second metal layer includes the first gate electrode, the first source electrode and the first drain electrode; the first gate electrode is located in the middle region of the first active layer, the first drain electrode is erected on the drain connection region, and is connected with the first connection electrode through the first via; and a first end of the first source electrode is connected with the first power supply line through the second via, and a second end of the first source electrode is erected on the source connection region;

etching the second insulating layer not covered by the second metal layer with the second metal layer and the photoresist disposed on the second metal layer as masks; and

performing a second conductorization treatment on the second electrode plate and the first active layer not covered by the second insulating layer with the second insulating layer, the second metal layer disposed on the second insulating layer and the photoresist disposed on the second metal layer as masks, to form the channel region of the first active layer and the source transition region and the drain transition region located at two sides of the channel region; wherein a boundary of an orthographic projection of the first gate electrode on the substrate base is located within a boundary range of an orthographic projection of the second insulating layer on the substrate base, and a boundary of an orthographic projection of the channel region on the substrate base is located within the range boundary of the orthographic projection of the second insulating layer on the substrate base, and the source transition region and the drain transition region each include the first region away from the channel region and the second region close to the channel region; and the conductivity of the first active layer corresponding to the first region is higher than the conductivity of the first active layer corresponding to the second region, or the oxygen content of the first active layer corresponding to the first region is less than the oxygen content of the first active layer corresponding to the second region, or the thickness of the first active layer corresponding to the first region is less than the thickness of the first active layer corresponding to the second region.

In an exemplary implementation, the forming the second insulating layer and the second metal layer including the first gate electrode sequentially, and the forming, by performing the two conductorization treatments, the channel region, the source transition region and the drain transition region located at two sides of the channel region, the source connection region located at the side of the source transition region away from the channel region and the drain connection region located at the side of the drain transition region away from the channel region in the first active layer, includes:

forming the second insulating layer covering the first active layer, wherein the second insulating layer is formed with a first via, a second via, a first active via and a second active via, the first via and the second via respectively expose the first connection electrode and the first power supply line, and the first active via and the second active via respectively expose partial regions at two sides of the first active layer;

performing a first conductorization treatment on the second electrode plate and the first active layer exposed in the first active via and the second active via, to form the second electrode plate conductorized and the source connection region and the drain connection region of the first active layer;

forming the second metal layer and retaining a photoresist on the second metal layer; wherein the second metal layer includes the first gate electrode, the first source electrode and the first drain electrode; the first gate electrode is located in a middle region of the active layer, the first drain electrode is connected with the drain connection region through the second active via, and is connected with the first connection electrode through the first via; a first end of the first source electrode is connected with the first power supply line through the second via, and a second end of the first source electrode is connected with the source connection region through the first active via;

etching the second insulating layer not covered by the second metal layer with the second metal layer and the photoresist disposed on the second metal layer as masks; and

performing a second conductorization treatment on the second electrode plate and the first active layer not covered by the second insulating layer with the second insulating layer, the second metal layer disposed on the second insulating layer and the photoresist disposed on the second metal layer as masks, to form the channel region of the first active layer and the source transition region and the drain transition region located at two sides of the channel region, wherein a boundary of an orthographic projection of the first gate electrode on the substrate base is located within a boundary range of an orthographic projection of the second insulating layer on the substrate base, and a boundary of an orthographic projection of the channel region on the substrate base is located within the range boundary of the orthographic projection of the second insulating layer on the substrate base, and the source transition region and the drain transition region each include the first region away from the channel region and the second region close to the channel region; and the conductivity of the first active layer corresponding to the first region is higher than the conductivity of the first active layer corresponding to the second region, or the oxygen content of the first active layer corresponding to the first region is less than the oxygen content of the first active layer corresponding to the second region, or the thickness of the first active layer corresponding to the first region is less than the thickness of the first active layer corresponding to the second region.

In an exemplary implementation, the etching the second insulating layer not covered by the second metal layer includes:

removing, by self-alignment etching, the second insulating layer between the first gate electrode and the first source electrode and the second insulating layer between the first gate electrode and the first drain electrode.

Other aspects will become apparent upon reading and understanding accompanying drawings and the detailed description.

### BRIEF DESCRIPTION OF THE DRAWINGS

Accompanying drawings are used to provide further understanding of technical solutions of the present disclosure, constitute a part of the specification, and are used to explain the technical solutions of the present disclosure together with embodiments of the present disclosure, thus do not constitute a limitation on the technical solutions of the present disclosure. The shapes and sizes of each component in the accompanying drawings do not reflect the true scale, but are only intended to schematically describe the contents of the present disclosure.

FIG. 1 is a schematic diagram of a structure of an OLED display unit according to an exemplary embodiment of the present disclosure;

FIG. 2 is a schematic diagram of an equivalent circuit of an OLED pixel driving circuit;

FIG. 3 is a schematic diagram after forming of a pattern of a first electrode plate according to an exemplary embodiment of the present disclosure;

FIG. 4 is a sectional view taken along a direction A-A in FIG. 3;

FIG. 5 is a schematic diagram after forming of a pattern of a metal oxide layer is formed according to an exemplary embodiment of the present disclosure;

FIG. 6 is a sectional view taken along a direction A-A in FIG. 5;

FIG. 7 is a schematic diagram after forming of a pattern of a second insulating layer according to an exemplary embodiment of the present disclosure;

FIG. 8 is a sectional view taken along a direction A-A in FIG. 7;

FIG. 9 is a schematic view after a first conductorization treatment according to an exemplary embodiment of the present disclosure;

FIG. 10 is a schematic diagram after forming of a pattern of a second metal layer according to an exemplary embodiment of the present disclosure;

FIG. 11 is a sectional view taken along a direction A-A in FIG. 10;

FIG. 12 is a schematic view after a second etching treatment according to an exemplary embodiment of the present disclosure;

FIG. 13a, FIG. 13b, and FIG. 13c are schematic views after a second conductorization treatment according to an exemplary embodiment of the present disclosure;

FIG. 14 is a schematic diagram after forming of a pattern of a third insulating layer according to an exemplary embodiment of the present disclosure;

FIG. 15 is a schematic diagram after forming of a pattern of a color filter layer according to an exemplary embodiment of the present disclosure;

FIG. 16 is a schematic diagram after forming of a pattern of a planarization layer according to an exemplary embodiment of the present disclosure;

FIG. 17 is a schematic diagram after forming of a pattern of an anode according to an exemplary embodiment of the present disclosure;

FIG. 18 is a schematic diagram after forming of a pattern of a pixel define layer according to an exemplary embodiment of the present disclosure;

FIG. 19 is a schematic diagram after of another forming of a pattern of a second insulating layer according to an exemplary embodiment of the present disclosure;

FIG. 20 is a sectional view taken along a direction A-A in FIG. 19;

FIG. 21 is a schematic view after another first conductorization treatment according to an exemplary embodiment of the present disclosure;

FIG. 22 is a schematic diagram after another forming of a pattern of a second metal layer according to an exemplary embodiment of the present disclosure;

FIG. 23 is a sectional view taken along a direction A-A in FIG. 22;

FIG. 24 is a schematic view after another second etching treatment according to an exemplary embodiment of the present disclosure;

FIG. 25a, FIG. 25b, and FIG. 25c are schematic views after another second conductorization treatment according to an exemplary embodiment of the present disclosure; and

FIG. 26 is a schematic view of a part of a first active layer according to an exemplary embodiment of the present disclosure.

### DETAILED DESCRIPTION

Implementations herein may be implemented in multiple different forms. Those of ordinary skills in the art can readily appreciate a fact that the implementations and contents may be varied into various forms without departing from the spirit and scope of the present disclosure. Therefore, the present disclosure should not be construed as only being limited to the contents recorded in the following implementations. The embodiments in the present disclosure and features in the embodiments may be combined randomly with each other if there is no conflict.

In the accompanying drawings, a size of a constituent element, and a thickness of a layer or a region is sometimes exaggerated for clarity. Therefore, any one implementation of the present disclosure is not necessarily limited to dimensions shown in the drawings, and the shapes and sizes of the components in the accompanying drawings do not reflect actual scales. In addition, the accompanying drawings schematically show an ideal example, and any one implementation of the present disclosure is not limited to the shapes, values, or the like shown in the accompanying drawings.

Ordinal numerals such as "first", "second", and "third" herein are set to avoid confusion between constituent elements, but are not intended to limit in terms of quantity.

Herein, for convenience, wordings indicating orientations or positional relationships, such as "center", "upper", "lower", "front", "back", "vertical", "horizontal", "top", "bottom", "inside", "outside", and the like are used to describe the positional relationships between the constituent elements with reference to the accompanying drawings, and are merely for facilitating describing the implementations and simplifying the specification, rather than indicating or implying that the referred apparatuses or elements must have particular orientations, and be constructed and operated in particular orientations. Thus, they cannot be construed as a limitation on the present disclosure. The positional relationships between the constituent elements can be appropriately changed according to directions according to which the constituent elements are described. Therefore, appropriate replacements can be made according to situations without being limited to the wordings described in the specification.

Herein, unless otherwise specified and defined explicitly, terms "mount", "mutually connect", "connect" and the like should be understood in a broad sense. For example, a connection may be a fixed connection, or a detachable connection, or an integral connection, it may be a mechanical connection or an electrical connection, it may be a direct connection, or an indirect connection through an intermediate, or an internal communication between two elements. Those of ordinary skills in the art may understand the meanings of the above terms in the present disclosure according to situations.

Herein, a transistor refers to an element at least including three terminals, i.e., a gate electrode, a drain electrode, and a source electrode. A transistor has a channel region between a drain electrode (or referred to as a drain electrode terminal, a drain connection region, or a drain electrode) and a source electrode (or referred to as a source electrode terminal, a source connection region, or a source electrode), and a current can flow through the drain electrode, the channel region, and the source electrode. Herein, the channel region refers to a region through which the current mainly flows.

Herein, a first electrode may be the drain electrode, and a second electrode may be the source electrode; or the first electrode may be the source electrode, and the second electrode may be the drain electrode. Herein, functions of the "source electrode" and the "drain electrode" are sometimes interchangeable with each other in a case that transistors with opposite polarities are used or a current direction changes during circuit operation. Therefore, the "source electrode" and the "drain electrode" are interchangeable herein.

Herein, “electrical connection” includes a case that constituent elements are connected together by an element with a certain electrical effect. "The element with the certain electric action" is not particularly limited as long as electric signals between the connected constituent elements may be sent and received. For example, “the elements with the certain electrical effect” may be electrodes or wirings, or switch elements, such as transistors, or other functional elements, such as resistors, inductors, capacitors, or the like.

Herein, "parallel" refers to a state in which an angle formed by two straight lines is above -10° and below 10°, and thus also includes a state in which the angle is above -5° and below 5°. In addition, "vertical" refers to a state in which an angle formed by two straight lines is more than 80° and less than 100°. Therefore, it also includes a state in which an angle is more than 85° and less than 95°.

Herein, "film" and "layer" are interchangeable. For example, sometimes "conductive layer" may be replaced by "conductive film". Similarly, sometimes "insulating film" may be replaced by "insulating layer".

"About” herein refers to that a boundary is defined not so strictly and numerical values within process and measurement error ranges are allowed.

With the rapid development of display technology, thin film transistor technology has developed from amorphous silicon (a-Si) thin film transistor to metal oxide (Oxide) thin film transistor. The carrier mobility of an oxide active layer is 20 ~ 30 times that of amorphous silicon active layer, and it has the characteristics of large mobility, high on-state current, better switch characteristics and better uniformity, which may greatly improve the characteristics of thin film transistors, improve the response speed of pixels and achieve faster refresh rate, and may be applied to applications requiring fast response and large current.

There are two types of oxide thin film transistors, they are a bottom-gate type thin film transistor and a top-gate type thin film transistor. A structure of the bottom-gate type thin film transistors is characterized in that a source electrode and a drain electrode respectively cover two sides of an oxide active layer, and a channel region is formed between the source electrode and the drain electrode. A structure of the top-gate type thin film transistor is characterized in that a source electrode and a drain electrode are respectively connected with an oxide active layer through a via. Since the top-gate type thin film transistor has a characteristic of short channel, the on-state current (Ion) may be effectively improved, thus significantly improving the display effect, and effectively reducing the power consumption. Due to a small overlapping area between the gate electrode and the source and drain electrodes, small parasitic capacitance generated, small circuit delay and high switch speed in the top-gate type thin film transistor, the possibility of gate-drain short circuit (GDS) is low.

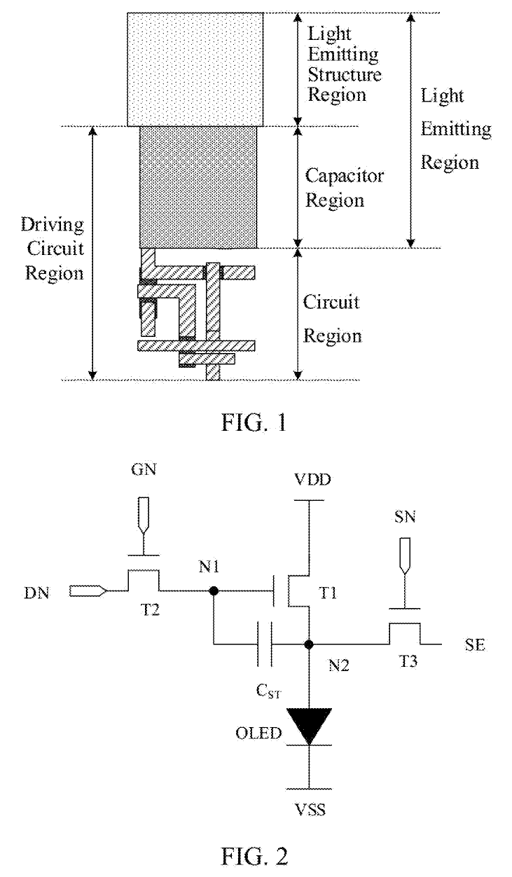

Exemplary embodiments of the present disclosure provide a bottom-emitting type display substrate including multiple display units (sub-pixels) arranged regularly. FIG. 1 is a schematic diagram of a structure of an OLED display unit according to an exemplary embodiment of the present disclosure. As shown in FIG. 1, in a plane parallel to the display substrate, each display unit includes a light emitting structure region provided with a light emitting structure configured to emit light and a driving circuit region provided with a pixel driving circuit configured to drive the light emitting structure, the pixel driving circuit may include multiple thin film transistors and a storage capacitor.

In an exemplary implementation, the driving circuit region may include a circuit region in which the multiple thin film transistors driving the light emitting structure are disposed, and a capacitor region in which electrode plates of the storage capacitor are disposed. The electrode plates of the storage capacitor and the multiple thin film transistors are disposed in parallel.

In an exemplary implementation, the storage capacitor is a transparent capacitor structure, which adopts a transparent conductive layer and a conductorized metal oxide as two electrode plates of the storage capacitor. Thus, the light emitting structure region and the capacitor region together constitute a light emitting region which can not only ensure the capacity of the storage capacitor, but also improve the pixel aperture ratio.

In an exemplary implementation, the pixel driving circuit may adopt a driving structure such as 3T1C, 4T1C, 5T1C, 6T1C, or 7T1C, which is not limited in the present disclosure.

FIG. 2 is a schematic diagram of an equivalent circuit of an OLED pixel driving circuit, which illustrates a 3T1C driving structure. As shown in FIG. 2, the pixel driving circuit is electrically connected with a first scan line GN, a second scan line SN, a data line DN, the first power supply VDD and a compensation line SE, and includes a first transistor T1, a second transistor T2, a third transistor T3 and a storage capacitor C_{ST.} In an exemplary implementation, the first transistor T1 is a driving transistor, the second transistor T2 is a switch transistor, and the third transistor T3 is a compensation transistor. In an exemplary implementation, a gate electrode of the first transistor T1 is connected with a second electrode of the second transistor T2 and a first electrode of the storage capacitor C_{ST}, a first electrode of the first transistor T1 is connected with the first power supply VDD, and a second electrode of the first transistor T1 is connected with a second electrode of the storage capacitor C_{ST} and a second electrode of the third transistor T3. A gate electrode of the second transistor T2 is connected with the first scan line GN, and a first electrode of the second transistor T2 is connected with the data line DN; a gate electrode of the third transistor T3 is connected with the second scan line SN, and a first electrode of the third transistor T3 is connected with the compensation line SE. An anode of an OLED is connected with the second electrode of the first transistor T1, and a cathode of the OLED is connected with a second power supply VSS. The OLED is configured to emit light with corresponding brightness in response to a current of the second electrode of the first transistor T1. In an exemplary implementation, the third transistor T3 may extract a threshold voltage Vth and mobility of the first transistor T1 in response to a compensation timing to compensate the threshold voltage Vth, and the storage capacitor C_{ST} is configured to maintain voltages of a node N1 and a node N2 within a light emitting period of one frame.

In an exemplary embodiment of the present disclosure, a display substrate with a bottom-emitting type top-gate structure includes a first metal layer, a first insulating layer, a metal oxide layer, a second insulating layer, and a second metal layer which are stacked; the metal oxide layer includes a first active layer, and the second metal layer includes a first gate electrode, a first source electrode, and a first drain electrode; the first active layer includes a channel region, a source transition region and a drain transition region located at two sides of the channel region, a source connection region located at a side of the source transition region away from the channel region and a drain connection region located at a side of the drain transition region away from the channel region; the source connection region is connected with the first source electrode, and the drain connection region is connected with the first drain electrode; the source transition region and the drain transition region each include a first region remote from the channel region and a second region close to the channel region; a conductivity of the first active layer corresponding to the first region is higher than a conductivity of the first active layer corresponding to the second region, or, oxygen content of the first active layer corresponding to the first region is less than oxygen content of the first active layer corresponding to the second region, or a thickness of the first active layer corresponding to the first region is less than a thickness of the first active layer corresponding to the second region.

In an exemplary implementation, the conductivity of the first active layer corresponding to the first region is higher than a conductivity of the first active layer corresponding to the source connection region and the drain connection region, or, the oxygen content of the first active layer corresponding to the first region is less than oxygen content of the first active layer corresponding to the source connection region and the drain connection region, or the thickness of the first active layer corresponding to the first region is less than a thickness of the first active layer corresponding to the source connection region and the drain connection region.

In an exemplary implementation, a boundary of an orthographic projection of the first gate electrode on the substrate base is within a boundary range of an orthographic projection of the second insulating layer on the substrate base; a boundary of an orthographic projection of the channel region on the substrate base is within the boundary range of the orthographic projection of the second insulating layer on the substrate base.

In an exemplary implementation, the display substrate further includes a first conductive layer, the first conductive layer includes a first electrode plate disposed on the substrate base, and the metal oxide layer includes a second electrode plate on which two conductorization treatments are performed, an orthographic projection of the second electrode plate on the substrate base and an orthographic projection of the first electrode plate on the substrate base have an overlapping region.

In an exemplary implementation, a material of the first electrode plate includes a transparent conductive material, and the overlapping region is located in the light emitting region of the display substrate.

In an exemplary implementation, the first metal layer includes the first power supply line and a first connection electrode connected with the first electrode plate, and a transparent conductive thin film is disposed between the first metal layer and the substrate base; an orthographic projection of the first connection electrode on the substrate base and an orthographic projection of the channel region of the first active layer on the substrate base have an overlapping region.

In an exemplary implementation, the first source electrode and the first drain electrode are disposed on the first insulating layer; the first drain electrode is erected on the drain connection region of the first active layer and is connected with the first connection electrode through a first via; a first end of the first source electrode is connected with the first power supply line through a second via, and a second end of the first source electrode is erected on the source connection region of the first active layer.

In an exemplary implementation, the first source electrode and the first drain electrode are disposed on the second insulating layer; the first drain electrode is connected with the drain connection region of the first active layer through a first active via and is connected with the first connection electrode through the first via; the first end of the first source electrode is connected with the first power supply line through the second via, and the second end of the first source electrode is connected with the source connection region of the first active layer through a second active via.

In an exemplary implementation, the source transition region of the first active layer is located between the first gate electrode and the first source electrode, and the drain transition region of the first active layer is located between the first gate electrode and the first drain electrode.

In an exemplary implementation, each sub-pixel includes a light emitting region and a circuit region, multiple transistors in the pixel driving circuit are disposed in the circuit region, and an orthographic projection of a storage capacitor in the pixel driving circuit on the substrate base has an overlapping region with the light emitting region.

In an exemplary implementation, the source connection region and the drain connection region of the first active layer are formed by a first conductorization treatment, and the channel region of the first active layer is formed during a second conductorization treatment of self-alignment.

A process of preparing the display substrate will be exemplarily described below. "Patterning process" mentioned in the present disclosure includes photoresist coating, mask exposure, development, etching, photoresist stripping and so on for metal materials, inorganic materials or transparent conductive materials, and includes organic material coating, mask exposure, development and so on for organic materials. Deposition may be implemented by adopting any one or more of sputtering, evaporation and chemical vapor deposition. Coating may be implemented by adopting any one or more of spray coating, spin coating and inkjet printing, and etching may be implemented by adopting any one or more of dry etching and wet etching, which are not limited in the present disclosure. "Thin film" refers to a layer of thin film formed by a certain material on a substrate base through deposition, coating or other processes. If a "thin film" does not need the patterning process in the whole preparing process, the "thin film" may also be referred to as a "layer". If a "thin film" needs the patterning process in the whole preparing process, it is referred to as "thin film" before the patterning process and "layer" after the patterning process. A "layer" obtained after the patterning process includes at least one "pattern". “A and B are disposed in the same layer” in the present disclosure means that A and B are formed at the same time through a same patterning process, and a “thickness” of a film layer is a size of the film layer in a direction perpendicular to the display substrate. In an exemplary embodiment of the present disclosure, "an orthographic projection of A includes an orthographic projection of B" refers to that a boundary of the orthographic projection of B falls within a boundary of the orthographic projection of A, or the boundary of the orthographic projection of A overlaps with the boundary of the orthographic projection of B.

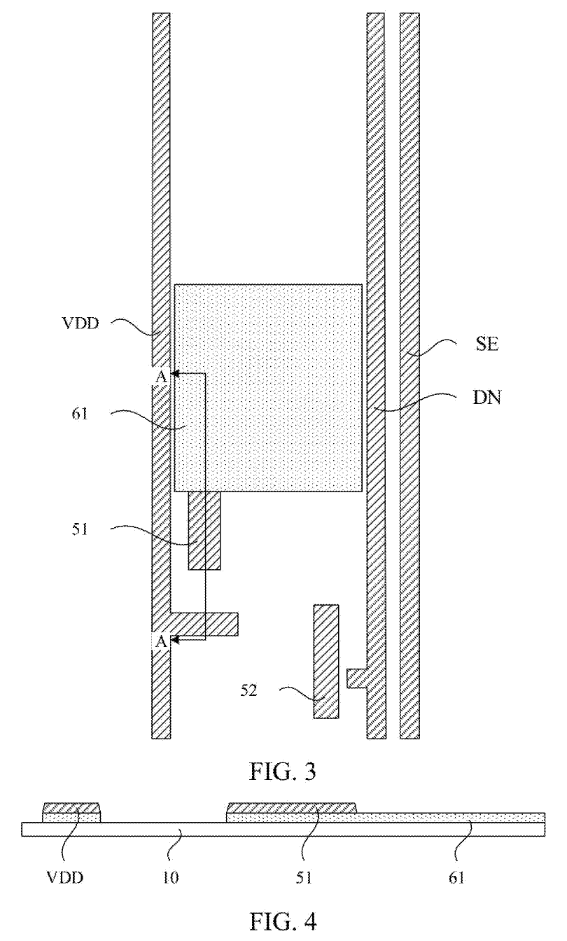

In an exemplary implementation, a preparation process for the display substrate may include the following operations, as shown in FIG. 3 to FIG. 18.

(1) Patterns of a first electrode plate and a first metal layer are formed. In an exemplary implementation, forming of the patterns of the first electrode plate and the first metal layer may include: depositing a first transparent conductive thin film and a first metal thin film on a substrate base sequentially, patterning the first transparent conductive thin film and the first metal thin film by a halftone patterning process, forming patterns of a first electrode plate 61 and a first metal layer on the substrate base 10. The pattern of the first metal layer includes at least a first power supply line VDD, a data line DN, a compensation line SE, a first connection electrode 51 and a second connection electrode 52, a first connection electrode 51 is connected with the first electrode plate 61, as shown in FIG. 3 and FIG. 4. FIG. 4 is a sectional view in an A-A direction in FIG. 3.

In an exemplary implementation, patterning of the first transparent conductive thin film and the first metal thin film by the halftone patterning process may include: first, coating a layer of photoresist on the first metal thin film, exposing the photoresist by a halftone mask, forming a pattern of the photoresist after development. The pattern of the photoresist includes an unexposed region, a partially exposed region and a fully exposed region. The unexposed region includes positions where the patterns of the first power supply line VDD, the data line DN, the compensation line SE, the first connection electrode 51 and the second connection electrode 52 are located. The photoresist of the unexposed region has a first thickness. The partially exposed region includes a position where the first electrode plate 61 is located, and the photoresist of the partially exposed region has a second thickness, the second thickness is less than the first thickness. The other region is the fully exposed region, and the photoresist of the fully exposed region is completely removed to expose a surface of the first metal thin film. Subsequently, the first transparent conductive thin film and the first metal thin film in the fully exposed region are removed by a first etching process. Subsequently, the photoresist of the partially exposed region is removed by an ashing process, to expose the surface of the first metal thin film in the partially exposed region. Subsequently, the first metal thin film of the partially exposed region is removed by a second etching process, to expose the first transparent conductive thin film in the partially exposed region. Finally, the remaining photoresist is stripped off to form the patterns of the first electrode plate and the first metal layer on the substrate base. After this patterning process, a transparent conductive thin film is retained below the first metal layer (the first power supply line VDD, the data line DN, the compensation line SE, the first connection electrode 51 and the second connection electrode 52).

In an exemplary implementation, the first power supply line VDD, the data line DN, and the compensation line SE are parallel to each other and extend in a vertical direction, the first power supply line VDD is disposed at side of a sub-pixel, and the data line DN and the compensation line SE are disposed at another side of the sub-pixel. The first power supply line VDD is configured to supply a power signal to a first source electrode of a first transistor, the data line DN is configured to supply a data signal to a second source electrode of a second transistor, and the compensation line SE is configured to supply a compensation signal to a third source electrode of a third transistor.

In an exemplary implementation, the first electrode plate 61 is configured to form a storage capacitor with a second electrode plate in a metal oxide layer formed subsequently. The first connection electrode 51 is connected with the first electrode plate 61, and is configured to, on the one hand, be connected with a first drain electrode of the first transistor and a third drain electrode of the third transistor which are formed subsequently, to achieve the connection of the first electrode plate 61 with the first drain electrode and the third drain electrode, and on the other hand, to serve as a shielding layer of the first transistor T1. The second connection electrode 52 is configured to be connected with a third gate electrode of the third transistor formed subsequently.

In an exemplary implementation, a thickness of the first transparent conductive thin film is about 40nm to 150nm, and a thickness of the first metal thin film is about 100nm to 1000nm.

In some possible implementations, the first electrode plate of the first conductive layer may be configured to form a storage capacitor with a second metal layer formed subsequently. Alternatively, the first electrode plate of the first conductive layer may be configured to form a storage capacitor with a pixel electrode formed subsequently, which is disposed in the same layer and formed by the same patterning process as an anode.

In some possible implementations, the first electrode plate may be disposed on the first metal layer, the first electrode plate of the first metal layer is configured to form a storage capacitor with the second metal layer formed subsequently, or the first electrode plate of the first metal layer is configured to form a storage capacitor with the pixel electrode formed subsequently.

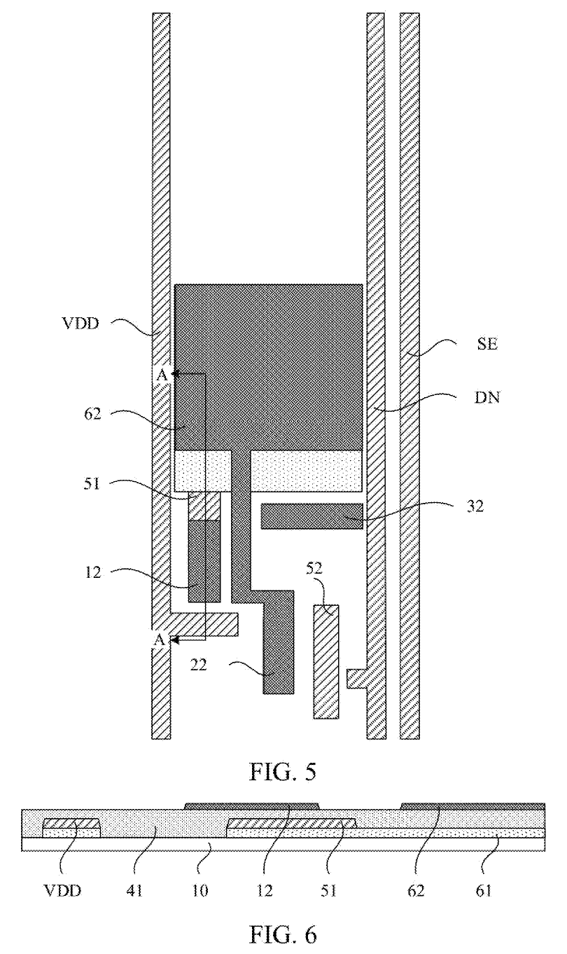

(2) A pattern of a metal oxide layer is formed. In an exemplary implementation, forming of the pattern of the metal oxide layer may include: depositing a first insulating thin film and a metal oxide thin film sequentially on the substrate base formed with the aforementioned patterns, and patterning the metal oxide thin film by a patterning process to form a first insulating layer 41 covering the patterns of the first electrode plate 61 and the first metal layer, and patterns of a first active layer 12, a second active layer 22, a third active layer 32 and a second electrode plate 62 formed on the first insulating layer 41, as shown in FIG. 5 and FIG. 6. FIG. 6 is a sectional view taken along a direction A-A in FIG. 5.

In an exemplary implementation, the first active layer 12 serves as an active layer of a driving TFT (first transistor T1), an orthographic projection of the first active layer 12 on the substrate base overlaps with an orthographic projection of the first connection electrode 51 on the substrate base. The second active layer 22 serves as an active layer of a switch TFT (second transistor T2), the second active layer 22 is connected with the second electrode plate 62. The third active layer 32 serves as an active layer of a compensation TFT (third transistor T3). A position of the second electrode plate 62 corresponds to a position of the first electrode plate 61, that is, an orthographic projection of the second electrode plate 62 on the substrate base overlaps with an orthographic projection of the first electrode plate 61 on the substrate base, so that the first electrode plate 61 and the second electrode plate 62 form a storage capacitor with a transparent structure. In some possible implementations, an orthographic projection of the second electrode plate 62 on the substrate base is located within a range of an orthographic projection of the first electrode plate 61 on the substrate base.

In an exemplary implementation, the metal oxide layer may be made of oxides containing indium and tin, oxides containing tungsten and indium, oxides containing tungsten, indium and zinc, oxides containing titanium and indium, oxides containing titanium, indium and tin, oxides containing indium and zinc, oxides containing silicon, indium and tin, oxides containing indium, gallium and zinc, etc. In some possible implementations, the metal oxide layer may be made of transparent indium gallium zinc oxide (IGZO) or indium tin zinc oxide (ITZO).

In an exemplary implementation, a thickness of the first insulating thin film is about 200nm to 1000nm, and a thickness of the metal oxide thin film is about 20nm to 200nm.

In some possible implementations, the second electrode plate in the metal oxide layer may be configured to form a storage capacitor with the second metal layer formed subsequently, or may be configured to form a storage capacitor with the pixel electrode formed subsequently, or may be configured to form a storage capacitor with the first metal layer.

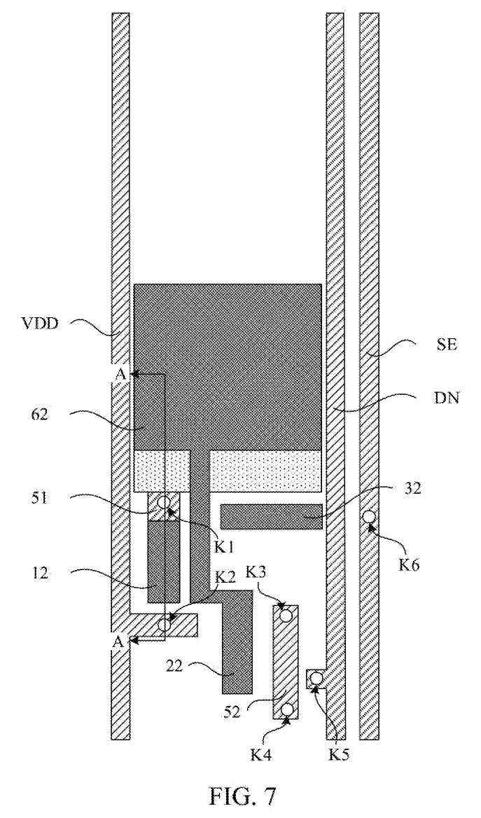

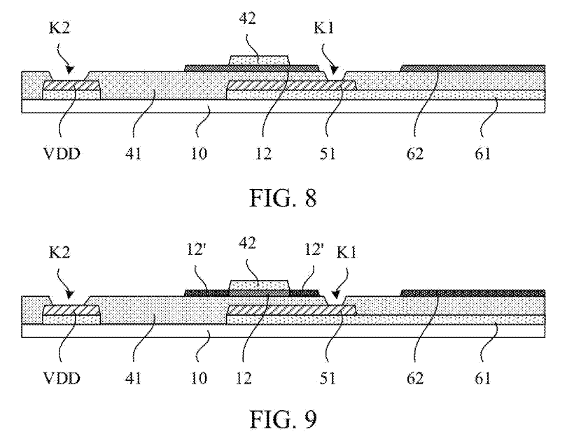

(3) A pattern of a second insulating layer is formed. In an exemplary implementation, forming of the pattern of the second insulating layer may include: depositing a second insulating thin film on the substrate base formed with the aforementioned patterns, patterning the second insulating thin film by a halftone patterning process, forming a pattern of a second insulating layer 42 and patterns of multiple vias disposed on the first insulating layer 41. The pattern of the second insulating layer 42 is located at positions where the first active layer 12, the second active layer 22, and the third active layer 32 are located, and the patterns of the multiple vias include at least a first via K1, a second via K2, a third via K3, a fourth via K4, a fifth via K5, and a sixth via K6, as shown in FIG. 7 and FIG. 8. FIG. 8 is a sectional view in an A-A direction in FIG. 7.

In an exemplary implementation, patterning of the second insulating thin film by the halftone patterning process may include: first, coating a layer of photoresist on the second insulating thin film, exposing the photoresist by a halftone mask, and forming a pattern of the photoresist after development. The pattern of the photoresist includes an unexposed region, a partially exposed region and a fully exposed region. The unexposed region includes positions where the first active layer 12, the second active layer 22 and the third active layer 32 are located. The photoresist of the unexposed region has a first thickness. The fully exposed region includes positions where the patterns of vias are located, and the photoresist of the fully exposed region is completely removed to expose a surface of the second insulating thin film. The other region is the partially exposed region, and the photoresist of the partially exposed region has a second thickness, the second thickness is less than the first thickness. Subsequently, the second insulating thin film and the first insulating layer 41 of the fully exposed region are removed by a first etching process to form the patterns of the multiple vias. Subsequently, the photoresist in the partially exposed region is removed by an ashing process to expose the second insulating thin film in the partially exposed region. Subsequently, the second insulating thin film of the partially exposed region is removed by a second etching process. Finally, the remaining photoresist is stripped off to form the pattern of the second insulating layer 42 and the patterns of the multiple vias disposed on the first insulating layer 41.

In an exemplary implementation, the multiple vias include the first via K1, the second via K2, the third via K3, the fourth via K4, the fifth via K5, and the sixth via K6. The first via K1 is located at a position where the first connection electrode 51 is located and exposes a surface of the first connection electrode 51. The first via K1 is configured to connect the first drain electrode of the first transistor and the third drain electrode of the third transistor formed subsequently with the first connection electrode 51, to achieve the connection of the first electrode plate 61 with the first drain electrode and the third drain electrode. The second via K2 is located at a position where the first power supply line VDD is located and exposes a surface of the first power supply line VDD. The second via K2 is configured to connect the first source electrode of the first transistor formed subsequently with the first power supply line VDD. The third via K3 and the fourth via K4 are respectively located at two ends of the second connection electrode 52 and expose a surface of the second connection electrode 52. The third via K3 and the fourth via K4 are configured to be connected with the second scan line SN and the third gate electrode of the third transistor formed subsequently, respectively, to achieve the connection of the second scan line SN with the third gate electrode. The fifth via K5 is located at a position where the data line DN is located and exposes a surface of the data line DN. The fifth via K5 is configured to be connected with the second source electrode of the second transistor formed subsequently, to achieve the connection of the data line DN with second source electrode. The sixth via K6 is located at a position where the compensation line SE is located and exposes a surface of the compensation line SE. The sixth via K6 is configured to be connected with the third source electrode of the third transistor formed subsequently, to achieve the connection of the compensation line SE with the third source electrode.

In an exemplary implementation, the second insulating layer 42 at the position where the second electrode plate 62 is located is removed, to expose the second electrode plate 62.

In an exemplary implementation, the second insulating layer 42 located at the position where the first active layer 12, the second active layer 22, and the third active layer 32 are located covers a partial region of the first active layer 12, a partial region of the second active layer 22, and a partial region of the third active layer 32, respectively. The second insulating layer 42 located at the position where the first active layer 12 is located covers a middle region of the first active layer 12, and has a covering width larger than a design width of the channel region of the first active layer 12, and two side regions not covered by the second insulating layer 42 expose the surface of the first active layer 12. The second insulating layer 42 located at the position where the second active layer 22 is located covers a middle region of the second active layer 22, and has a covering width larger than a design width of the channel region of the second active layer 22, and two side regions not covered by the second insulating layer 42 expose the surface of the second active layer 22. The second insulating layer 42 located at the position where the third active layer 32 is located covers a middle region of the third active layer 32, and has a covering width larger than a design width of the channel region of the third active layer 32, and two side regions not covered by the second insulating layer 42 expose the surface of the third active layer 32. Thus, each of the first active layer 12, the second active layer 22, and the third active layer 32 may form a wider channel region when a first conductorization treatment is performed subsequently.

In an exemplary implementation, the thickness of the second insulating thin film may be about 100nm to 500nm.

(4) A first conductorization treatment is performed. In an exemplary implementation, the first conductorization treatment may include: on the substrate base formed with the aforementioned patterns, performing a conductorization treatment on the two side regions of the first active layer 12, the second active layer 22, and the third active layer 32 not covered by the second insulating layer 42 and the second electrode plate 62, to form the second electrode plate 62 conductorized. The middle regions of the first active layer 12, the second active layer 22, and the third active layer 32 covered by the second insulating layer 42 form channel regions, the two side regions not covered by the second insulating layer 42 are processed as conductorized regions 12' which serve as a source connection region and a drain connection region of the first active layer 12, a source connection region and a drain connection region of the second active layer 22, and a source connection region and a drain connection region of the third active layer 32, respectively, as shown in FIG. 9.

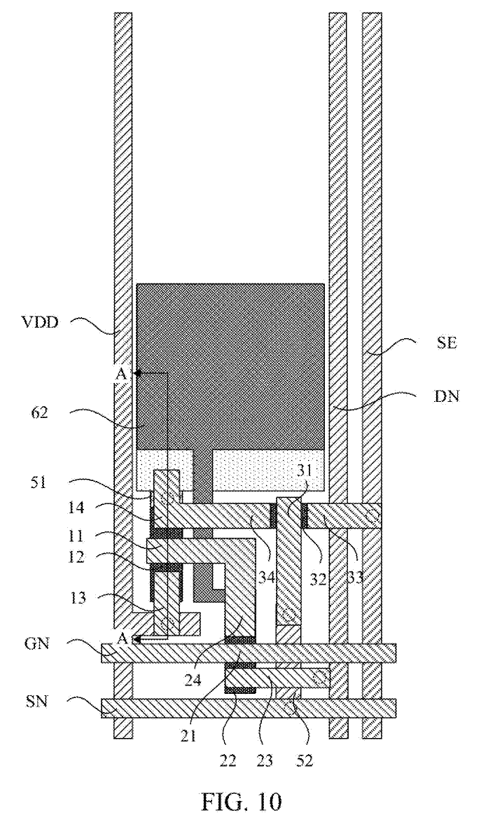

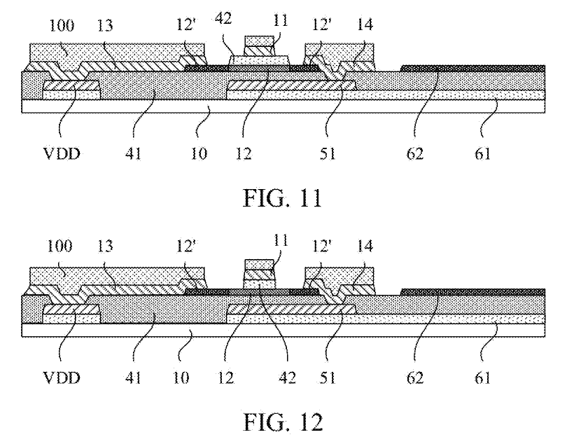

(5) A pattern of a second metal layer is formed. In an exemplary implementation, forming of the pattern of the second metal layer may include: depositing a second metal thin film on the substrate base formed with the aforementioned patterns; coating a layer of photoresist on the second metal thin film; forming a pattern of the photoresist by masking, exposure and development; etching the second metal thin film by a first etching process to form the pattern of the second metal layer; and retaining the photoresist 100 on the second metal layer. The pattern of the second metal layer includes at least a first scan line GN, a second scan line SN, a first gate electrode 11, a second gate electrode 21, a third gate electrode 31, a first source electrode 13, a first drain electrode 14, a second source electrode 23, a second drain electrode 24, a third source electrode 33, and a third drain electrode 34, as shown in FIG. 10 and FIG. 11. FIG. 11 is a sectional view in an A-A direction in FIG. 10.

In the exemplary implementation, the first scan line GN and the second scan line SN are parallel to each other, extend in a horizontal direction, and are both disposed on a lower side of the sub-pixel. The first scan line GN may be a switch scan line, and configured to provide the second gate electrode of the second transistor with an on/off signal for controlling the second transistor. The second scan line SN may be a compensation scan line, and configured to provide the third gate electrode of the third transistor with an on/off signal for controlling the third transistor, and the second scan line SN is connected with the second connection electrode 52 through the fourth via K4.

In an exemplary implementation, the first gate electrode 11 and the second drain electrode 24 are connected with each other as an integral structure, the second gate electrode 21 and the first scan line GN are connected with each other as an integral structure, the third gate electrode 31 is connected with the second connection electrode 52 through the third via K3. Since the second connection electrode 52 is connected with the second scan line SN through the fourth via K4, the third gate electrode 31 is connected with the second scan line SN through the second connection electrode 52.

In an exemplary implementation, a first end of the first source electrode 13 is connected with the first power supply line VDD through the second via K2, and the second end of the first source electrode 13 is erected on a source connection region where the first active layer 12 is conductorized, to form the first source electrode 13 connected with the first power supply line VDD. A first end of the first drain electrode 14 is erected on a drain connection region where the first active layer 12 is conductorized, and is connected with the first connection electrode 51 through the first via K1, to achieve the connection of the first drain electrode 14 with the first electrode plate 61. A second end of the first drain electrode 14 is erected on a drain connection region where the third active layer 32 is conductorized, to form the first drain electrode 14 and the third drain electrode 34 in an integral structure.

In an exemplary implementation, a first end of the second source electrode 23 is connected with the data line DN through the fifth via K5, and a second end of the second source electrode 23 is erected on a source connection region where the second active layer 22 is conductorized, to form the second source electrode 23 connected with the data line DN. A first end of the second drain electrode 24 is erected on a drain connection region where the second active layer 22 is conductorized, and a second end of the second drain electrode 24 is erected on a channel region where the second active layer 22 is not conductorized, to form the second drain electrode 24 and the first gate electrode 11 in an integral structure, and achieve the connection of the second drain electrode 24 with the second electrode plate 62.

In an exemplary implementation, a first end of the third source electrode 33 is connected with the compensation line SE through the sixth via K6, and a second end of the third source electrode 33 is erected on a source connection region where the third active layer 32 is conductorized, to form the third source electrode 33 connected with the compensation line SE. The third drain electrode 34 is erected on a drain connection region where the third active layer 32 is conductorized, and third drain electrode 34 and the first drain electrode 14 are connected with each other as an integral structure.

In an exemplary implementation, the first gate electrode 11, the first active layer 12, the first source electrode 13 and the first drain electrode 14 constitute a first transistor T1; the second gate electrode 21, the second active layer 22, the second source electrode 23, and the second drain electrode 24 constitute a second transistor T2; the third gate electrode 31, the third active layer 32, the third source electrode 33, and the third drain electrode 34 constitute a third transistor T3, and the first electrode plate 61 and the second electrode plate 62 conductorized constitute a storage capacitor with a transparent structure.

In an exemplary implementation, a thickness of the second metal thin film is about 100nm to 1000nm.

In some possible implementations, the second metal layer may form electrode plates of a capacitor, may be configured to form a storage capacitor with the first conductive layer, or may be configured to form a storage capacitor with the first metal layer, or may be configured to form a storage capacitor with the metal oxide layer, or may be configured to form a storage capacitor with a pixel electrode formed subsequently.

(6) A second etching treatment is performed. In an exemplary implementation, the second etching treatment may include: etching the second insulating layer 42 downward by the second etching process in self-alignment using the pattern of the second metal layer and the photoresist 100 remaining on the second metal layer as a mask, to remove the second insulating layer 42 not covered by the pattern of the second metal layer on the first active layer 12, the second active layer 22, and the third active layer 32, as shown in FIG. 12. In an exemplary implementation, since widths of the first gate electrode 11, the second gate electrode 21 and the third gate electrode 31 are very small, about 6µm to 10µm, a width of the second insulating layer 42 that is finally retained is close to the width of a second metal layer. A width of the second insulating layer 42 on the first active layer 12, the second active layer 22 and the third active layer 32 is close to a designed width of a channel region of the corresponding active layer. In an exemplary implementation, a boundary of an orthographic projection of the first gate electrode 11 on the substrate base is located within a boundary range of an orthographic projection of the second insulating layer 42 on the substrate base, and a boundary of an orthographic projection of the channel region of the active layer on the substrate base is located within a boundary range of the orthographic projection of the second insulating layer 42 on the substrate base.

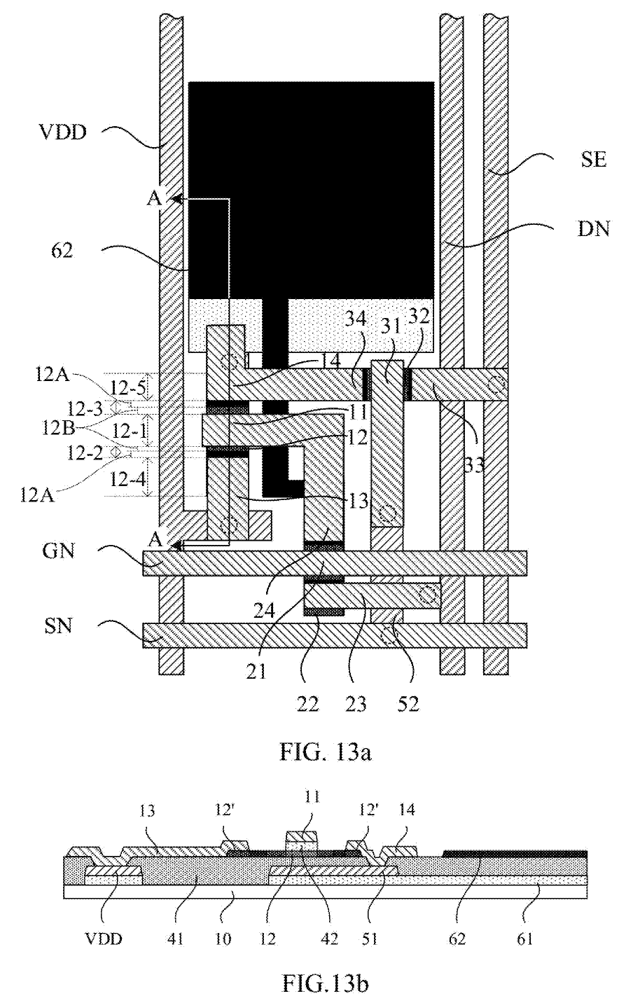

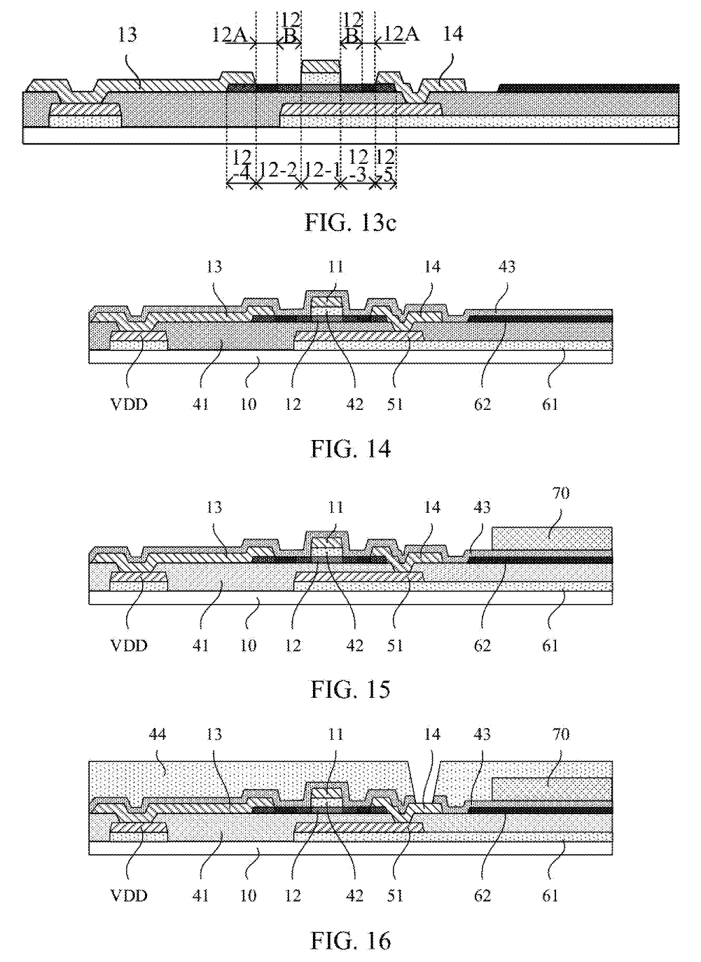

(7) A second conductorization treatment is performed. In an exemplary implementation, the second conductorization treatment may include: performing the second conductorization treatment on the first active layer 12, the second active layer 22, and the third active layer 32 using the second insulating layer 42, the pattern of the second metal layer disposed on the second insulating layer 42 and the photoresist 100 remaining on the second metal layer as a mask, while performing the second conductorization treatment on the second electrode plate 62, to form a channel region of a corresponding active layer and the second electrode plate 62 on which the second conductorization treatment is performed, and stripping off the remaining photoresist, as shown in FIG. 13a, FIG. 13b, and FIG. 13c, FIG. 13b and FIG. 13c are sectional views in an A-A direction in FIG. 13a. Since the second conductorization treatment is a self-alignment conductorization treatment using the second insulating layer 42, the pattern of the second metal layer, and the photoresist 100 as a mask, a width of the channel finally formed is substantially the same as that of the first gate electrode 11, the second gate electrode 21, and the third gate electrode 31, respectively. An orthographic projection of the channel region of the first active layer 12 on the substrate base overlaps with an orthographic projection of the first connection electrode 51 on the substrate base, so that the first connection electrode 51 shields the channel region of the first active layer 12. The exemplary embodiment of the present disclosure greatly improves the alignment accuracy between the gate electrode and the lower channel region, and greatly improves the electrical characteristics of the thin film transistor through the conductorization treatment of self-alignment.

In an exemplary implementation, the two condoctorization treatments are performed on the first active layer, so that three regions are formed in the first active layer: a channel region 12-1 located in the middle, a source transition region 12-2 and a drain transition region 12-3 located at two sides of the channel region 12-1, and a source connection region 12-4 located at a side of the source transition region 12-2 away from the channel region 12-1 and a drain connection region 12-5 located at a side of the drain transition region 12-3 away from the channel region 12-1. A boundary of an orthographic projection of the channel region 12-1 on the substrate base substantially overlaps with a boundary of an orthographic projection of the first gate electrode 11 on the substrate base. The source connection region 12-4 is connected with and covered by the first source electrode 13. The drain connection region 12-5 is connected with and covered by the first drain electrode 14. The source transition region 12-2 is located between the channel region 12-1 and the source connection region 12-4, i.e. located at a region between the first gate electrode 11 and the first source electrode 13, and the drain transition region 12-3 is located between the channel region 12-1 and the drain connection region 12-5, i.e. located at a region between the first gate electrode 11 and the first drain electrode 14. Similarly, three regions are also formed in the second active layer and the third active layer, respectively. Due to adoption of two conductorization treatments, a region on which the first conductorization treatment is performed overlaps with a region on which the second conductorization treatment is performed (as shown by black regions in FIG. 13a, FIG. 13b, and FIG. 13c), thus, both the source transition region 12-2 and the drain transition region 12-3 contain a first region 12A on which two conductorization treatments are performed, and a second region 12B on which only a second conductive process is performed. The first region 12A is away from the channel region 12-1, and the second region 12B is close to the channel region 12-1. In an exemplary implementation, two helium (He) plasma treatments are performed on the first region 12A on which two conductorization treatments are performed, oxygen content in the film layer is further reduced, and oxygen content of the first active layer corresponding to the first region 12A is less than oxygen content of the first active layer corresponding to the second region 12B, which is beneficial to improve the electrical characteristics of the thin film transistor. In an exemplary implementation, the first region 12A on which two conductorization treatments are performed has lower resistance and stronger conductivity, and the conductivity of the first active layer corresponding to the first region 12A is higher than the conductivity of the first active layer corresponding to the second region 12B, which is beneficial to improve the electrical characteristics of the thin film transistor. In an exemplary implementation, the oxygen content of the first active layer corresponding to the first region 12A is less than the oxygen content of the first active layer corresponding to the second region 12B, and the conductivity of the first active layer corresponding to the first region 12A is higher than the conductivity of the first active layer corresponding to the second region 12B. Since only the first conductorization treatment is performed on the source connection region and the drain connection region, the conductivity of the first active layer corresponding to the first region 12A is higher than the conductivity of the first active layer corresponding to the source connection region and the drain connection region, and the oxygen content of the first active layer corresponding to the first region 12A is less than the oxygen content of the first active layer corresponding to the source connection region and the drain connection region. Since the two conductorization treatments are performed on the second electrode plate 62, the conductibility of the second electrode plate 62 is improved, which is beneficial to improve the driving characteristics of the pixel driving circuit. In an exemplary implementation, the conductivity of the metal oxide layer corresponding to the second electrode plate 62 is higher than the conductivity of the first active layer corresponding to the second region 12B, or oxygen content of the metal oxide layer corresponding to the second electrode plate 62 is less than the oxygen content of the first active layer corresponding to the second region 12B.

In an exemplary implementation, a width of the first region 12A may be less than a width of the source connection region 12-4 or a width of the first region 12A may be less than a width of the drain connection region 12-5.

In an exemplary implementation, the width of the first region 12A may be less than a width of the second region 12B.

In an exemplary implementation, the width of the first region 12A may be less than a width of the channel region 12-1.

In an exemplary implementation, an orthographic projection of at least portion of the first region 12A in the source transition region 12-2 on the substrate base does not overlap with an orthographic projection of the first metal layer on the substrate base, or an orthographic projection of at least portion of the first region 12A in the drain transition region 12-3 on the substrate base does not overlap with an orthographic projection of the first metal layer on the substrate base.

During the two conductorization treatments of the exemplary embodiment of the present disclosure, two etching treatments are performed on the second insulating layer, over-etching of the etching process may etch away a part of the thickness of the first active layer 12, thus the thickness of the first active layer corresponding to the first region 12A becomes thinner. As shown in FIG. 26, the thickness of the first active layer corresponding to the first region 12A is less than the thickness of the first active layer corresponding to the second region 12B, the thickness of the first active layer corresponding to the first region 12A is less than the thickness of the first active layer corresponding to the source connection region 12-4 and the drain connection region 12-5, and the thickness of the first active layer corresponding to the first region 12A is less than the thickness of the first active layer corresponding to the channel region 12-1, which is beneficial to improve the conductorization effect. In an exemplary implementation, a thickness of the first active layer 12 corresponding to a partial region of the first region 12A may become zero i.e. a hollow structure is formed. In an exemplary implementation, the thickness of the metal oxide layer corresponding to the second electrode plate 62 is less than the thickness of the first active layer corresponding to the second region 12B.

(8) A pattern of a third insulating layer is formed. In an exemplary implementation, forming of the pattern of the third insulating layer may include: depositing a third insulating thin film on the substrate base formed with the aforementioned patterns and forming a third insulating layer 43 covering the aforementioned structure, as shown in FIG. 14.

In an exemplary implementation, a thickness of the third insulating thin film is about 200nm to 1000nm.

(9) A pattern of a color filter layer is formed. In an exemplary implementation, forming of the pattern of the color filter layer may include: sequentially forming a first color unit, a second color unit, and a third color unit, respectively, by a patterning process, on a substrate base formed with the aforementioned patterns, to form a color filter layer 70, as shown in FIG. 15. In the exemplary implementation, the color filter layer 70 is formed in the light emitting region and the capacitor region, and the first color unit may be a green unit, the second color unit may be a red unit, and the third color unit may be a blue unit. In some possible implementations, the color filter layer 70 may include other color units, such as white units or yellow units.

(10) A pattern of a planarization layer is formed. In an exemplary implementation, forming of the pattern of the planarization layer may include: coating a layer of a planarization thin film on the substrate base formed with the aforementioned patterns, etching the third insulating layer 43, after masking, exposure and development using the planarization thin film as a photoresist, to form a planarization layer 44 covering the aforementioned structure. A seventh via K7 is formed on the planarization layer 44, and the seventh via K7 is located at a position where the first drain electrode 14 is located. The planarization layer 44 and the third insulating layer 43 in the seventh via K7 are removed to expose the surface of the first drain electrode 14, as shown in FIG. 16.

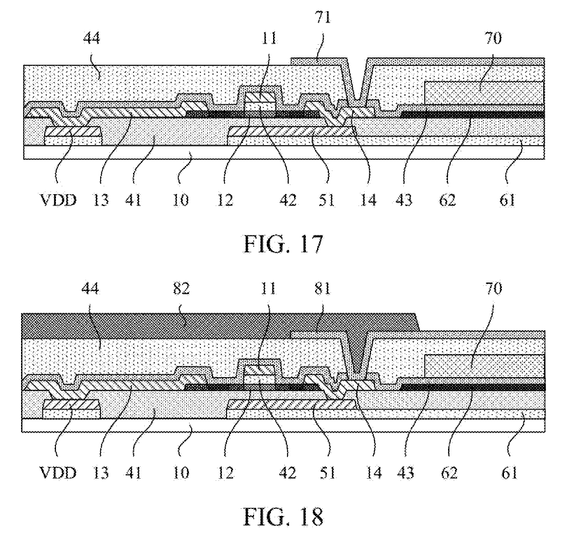

(11) A pattern of an anode is formed. In an exemplary implementation, forming of the pattern of the anode may include: depositing a second transparent conductive thin film on the substrate base formed with the aforementioned patterns, patterning the second transparent conductive thin film by a patterning process, to form a pattern of an anode 81. The anode 81 is connected with the first drain electrode 14 through the seventh via K7, as shown in FIG. 17. In an example implementation, the anode 81 is a transparent anode.

(12) A pattern of a pixel define layer is formed. In an exemplary implementation, forming the pattern of the pixel define layer includes: coating a pixel define thin film on the substrate base formed with the aforementioned patterns, and forming a pattern of a pixel define layer 82 by masking, exposure and development processes, the pixel define layer 82 defines an opening region KA exposing the anode 81, as shown in FIG. 18.

(13) Patterns of an organic light emitting layer, a cathode and an encapsulation layer etc. are formed, and the preparation method thereof is the same as that of the related art, which will not be repeated here. In an exemplary implementation, the cathode is a reflective cathode.

In an exemplary implementation, the organic light emitting layer may include a first light emitting sub-layer, a first charge generating layer, a second light emitting sub-layer, a second charge generating layer, and a third light emitting sub-layer which are stacked sequentially. The first light emitting sublayer is configured to emit a first color light, and includes a first hole transport layer (HTL), a first emitting material layer (EML), and a first electron transport layer (ETL) which are stacked sequentially. The second light emitting sublayer is configured to emit a second color light, and includes a second hole transport layer, a second emitting material layer and a second electron transport layer which are stacked sequentially. The third light emitting sublayer is configured to emit a third color light, and includes a third hole transport layer, a third emitting material layer and a third electron transport layer which are stacked sequentially. The first charge generating layer is disposed between the first light emitting sublayer and the second light emitting sublayer, and is configured to connect the two light emitting sublayers in series to achieve carrier transfer. The second charge generating layer is disposed between the second light emitting sublayer and the third light emitting sublayer, and is configured to connect the two light emitting sublayers in series to achieve carrier transfer. Since the organic light emitting layer includes a first emitting material layer emitting light of a first color, a second emitting material layer emitting light of a second color and a third light emitting material layer emitting light of a third color, thus light eventually emitted by the organic light emitting layer is mixed light. For example, it may be disposed that the first emitting material layer is a red light material layer emitting red light, the second emitting material layer is a green light material layer emitting green light, and the third emitting material layer is a blue light material layer emitting blue light, and thus the organic light emitting layer eventually emits white light. In an exemplary implementation, a structure of the organic light emitting layer may be designed according to an actual requirement. For example, in each light emitting sub-layer, in order to improve the efficiency of injecting electrons and holes into the emitting material layer, a hole injection layer (HIL) and an electron injection layer (EIL) may also be disposed. For another example, in order to simplify the structure of the organic light emitting layer, the first electron transport layer, the first charge generating layer and the second hole transport layer may be cancelled, that is, the second emitting material layer may be disposed directly on the first emitting material layer.

In an exemplary implementation, the first insulating layer, the second insulating layer, and the third insulating layer may be made of any one or more of silicon oxide (SiOx), silicon nitride (SiNx) and silicon nitride (SiON), and may be a single layer, multiple layers or a composite layer. The first insulating layer is referred to as a buffer layer configured for improving the water and oxygen resistance of the substrate base, the second insulating layer is referred to as a gate insulating (GI) layer, the third insulating layer is referred to as a passivation (PVX) layer. The first metal thin film and the second metal thin film may be made of a metal material, such as any one or more of silver (Ag), copper (Cu), aluminum (Al), titanium (Ti), and molybdenum (Mo), or an alloy material of the above metals, such as aluminum neodymium alloy (AlNd) or molybdenum niobium alloy (MoNb), and may be in a single-layer structure or multi-layer composite structure, such as Ti/Al/Ti. The first transparent conductive thin film and the second transparent conductive thin film may be made of indium tin oxide (ITO) or indium zinc oxide (IZO).

As shown in FIG. 3 to FIG. 18, the display substrate formed by the aforementioned preparation process may include: a substrate base 10; a transparent first electrode plate 61 disposed on the substrate base 10; a transparent conductive thin film disposed on the substrate base 10 and a first metal layer disposed on the transparent conductive thin film, the first metal layer includes at least a first power supply line VDD and a first connection electrode 51 connected with the first electrode plate 61; a first insulating layer 41 covering the first electrode plate 61 and the first metal layer, the first insulating layer 41 is disposed with a first via K1 and a second via K2, the first via K1 exposes the first connection electrode 51, and the second via K2 exposes the first power supply line VDD; a metal oxide layer disposed on the first insulating layer 41, the metal oxide layer includes at least a first active layer 12 and a second electrode plate 62 on which two conductorization treatments are performed, an orthographic projection of the second electrode plate 62 on the substrate base 10 overlaps with an orthographic projection of the first electrode plate 61 on the substrate base 10 to form a transparent storage capacitor; the first active layer 12 includes three regions: a channel region located in the middle, a source transition region and a drain transition region located at two sides of the channel region, and a source connection region located at a side of the source transition region away from the channel region and a drain connection region located at a side of the drain transition region away from the channel region; an orthographic projection of the channel region of the first active layer 12 on the substrate base 10 overlaps with an orthographic projection of the first connection electrode 51 on the substrate base 10; a second insulating layer 42 disposed on the first active layer 12 and a first gate electrode 11 disposed on the second insulating layer 42, a boundary of an orthographic projection of the first gate electrode 11 on the substrate base is within a boundary range of an orthographic projection of the second insulating layer 42 on the substrate base, and a boundary of the orthographic projection of the channel region of the first active layer 12 on the substrate base is within the boundary range of the orthographic projection of the second insulating layer 42 on the substrate base; a first source electrode 13 and a first drain electrode 14 disposed on the first insulating layer 41, a first end of the first source electrode 13 is connected with the first power supply line VDD through a second via K2, and a second end of the first source electrode 13 is erected on a source connection region of the first active layer 12; the first drain electrode 14 is erected on a drain connection region of the first active layer 12 and is connected with the first connection electrode 51 through the first via K1; a third insulating layer 43 covering the aforementioned structure; a color filter layer 70 is disposed on the third insulating layer 43; a planarization layer 44 covering the aforementioned structure, the planarization layer 44 is disposed with a seventh via K7 exposing

the first drain electrode 14; and an anode 81 disposed on the planarization layer 44, the anode 81 is connected with the first drain electrode 14 through the seventh via K7.

In an exemplary implementation, the display substrate may also include a pixel define layer, an organic light emitting layer, a cathode, and an encapsulation layer and the like.

In an exemplary implementation, the source transition region of the first active layer 12 is located between the first gate electrode 11 and the first source electrode 13, the drain transition region of the first active layer 12 is located between the first gate electrode 11 and the first drain electrode 14, and the second insulating layer 42 of the source transition region and the drain transition region is removed by self-alignment etching.

In an exemplary implementation, the source connection region and the drain connection region of the first active layer 12 are formed by a first conductorization treatment, and the channel region of the first active layer 12 is formed during a second conductorization treatment of self-alignment.

A pixel circuit layer of a display substrate with a transparent capacitor structure includes a shielding layer, a transparent conductive layer, a buffer layer, a semiconductor layer, a gate insulating layer, a gate metal layer, an interlayer insulating layer and a source-drain metal layer, and requires six patterning processes, which have many patterning processes, complex process flow, high production cost and low production capacity. The pixel circuit layer, the first conductive layer and the first metal layer of the display substrate provided by the exemplary embodiment of the present disclosure are formed by the same patterning process, the gate electrode, the source electrode and the drain electrode are disposed in the same layer and formed by the same patterning process, only four patterning processes are required, which greatly reduces the number of patterning processes. The preparation method for the display substrate of the embodiment of the present disclosure reduces the number of patterning processes, shortens the process time, reduces the process cost, has good process compatibility, high process realizability, strong practicability, is highly mass-produced, and has a good application prospect.

In a preparation process of a display substrate, a conductorization treatment is performed after a second insulating layer is formed and before a second metal layer is formed, to form a channel region with a fixed position and a length. However, in subsequent formation of a pattern of a gate electrode, due to the limitation of alignment accuracy of patterning process, a position of gate electrode is easy to deviate from the position of channel region, and it is difficult to align the gate electrode directly above the channel region, and the alignment accuracy between the gate electrode and the channel region is low. Alignment deviation between the gate electrode and the channel region will reduce the electrical characteristics of the thin film transistor, which will lead to an increase in turn-on voltage and a decrease in current, and affect the product performance. Exemplary embodiments of the present disclosure propose a solution of two conductorization treatments, the first conductorization treatment is performed before the formation of the second metal layer, a wider channel region is formed by the first conductorization treatment. The second conductorization treatment is performed after the formation of the second metal layer, the channel region and the gate electrode formed during the second conductorization treatment of self-alignment have higher alignment accuracy, which greatly improves the alignment accuracy between the gate electrode and the lower channel region and greatly improves the electrical characteristics of the thin film transistor.

In an exemplary embodiment of the present disclosure, a storage capacitor with a transparent structure is formed by adopting a first electrode plate and a second electrode plate of transparent material, the area of a layout occupied by the capacitor is saved, the pixel aperture ratio is effectively improved, and it is suitable for high PPI display.

In an exemplary embodiment of the present disclosure, by means of two etchings of the second insulating layer and two conductorization treatments, the source connection region and the drain connection region at two sides of the channel region have lower resistance and stronger conductivity, which is beneficial to improve the electrical characteristics of the thin film transistor.

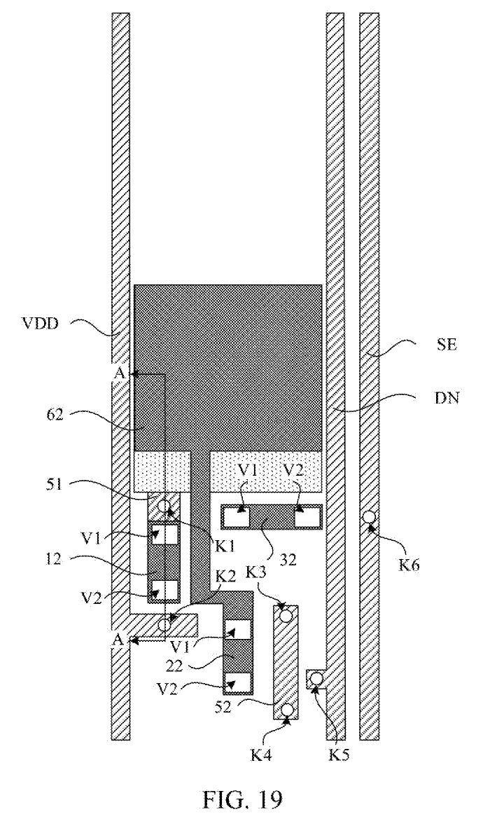

In another exemplary implementation, a preparation process for the display substrate may include the following operations, as shown in FIG. 19 to FIG. 25c.

(21) Patterns of a first electrode plate and a first metal layer are formed in the same manner as in the aforementioned process (1).

(22) A pattern of a metal oxide layer is formed in the same manner as in the aforementioned process (2).

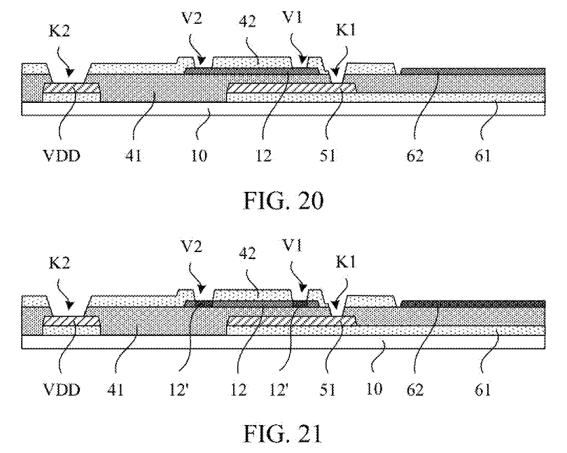

(23) A pattern of a second insulating layer is formed. In an exemplary implementation, forming of the pattern of the second insulating layer may include: depositing a second insulating thin film on the substrate base formed with the aforementioned patterns, patterning the second insulating thin film by a patterning process, to form the second insulating layer 42 covering the first active layer 12, the second active layer 22 and the third active layer 32. The second insulating layer 42 is disposed with patterns of multiple vias, the multiple vias at least include a first via K1, a second via K2, a third via K3, a fourth via K4, a fifth via K5, a sixth via K6, a first active via V1, and a second active via V2, as shown in FIG. 19 and FIG. 20. FIG. 20 is a sectional view along a direction A-A in FIG. 19.

In an exemplary implementation, the second insulating layer 42 located at a position where the second electrode plate 62 is located is removed to expose the second electrode plate 62.

In an exemplary implementation, the first insulating layer 41 and the second insulating layer 42 in the first via K1, the second via K2, the third via K3, the fourth via K4, the fifth via K5, and the sixth via K6 are etched away. The first via K1 is located at a position where the first connection electrode 51 is located and exposes the surface of the first connection electrode 51. The first via K1 is configured to connect the first drain electrode and the third drain electrode formed subsequently with the first connection electrode 51, to achieve the connection of the first electrode plate 61 with the first drain electrode and the third drain electrode. The second via K2 is located at a position where the first power supply line VDD is located and exposes the surface of the first power supply line VDD. The second via K2 is configured to connect the first source electrode formed subsequently with the first power supply line VDD. The third via K3 and the fourth via K4 are respectively located at two ends of the second connection electrode 52 and expose the surface of the second connection electrode 52. The third via K3 and the fourth via K4 are configured to be connected with the second scan line SN and the third gate electrode formed subsequently, respectively, to achieve the connection of the second scan line SN with the third gate electrode. The fifth Via K5 is located at a position of the data line DN and exposes the surface of the data line DN. The fifth Via K5 is configured to be connected with the second source electrode formed subsequently, to achieve the connection of the data line DN with the second source electrode. The sixth via K6 is located at a position of the compensation line SE and exposes the surface of the compensation line SE. The sixth via K6 is configured to be connected with the third source electrode formed subsequently, to achieve the connection of the compensation line SE with the third source electrode.

In an exemplary implementation, the second insulating layer 42 in the first active via V1 and the second active via V2 is etched away, to expose partial surfaces of regions on two sides of the first active layer 12, the second active layer 22 and the third active layer 32, respectively. A distance between the first active via V1 and the second active via V2 is greater than a design width of the channel regions of the first active layer 12, the second active layer 22 and the third active layer 32. Thus, each of the first active layer 12, the second active layer 22, and the third active layer 32 may form a wider channel region when the first conductorization treatment is performed subsequently.

(24) A first conductorization treatment is performed. In an exemplary implementation, the first conductivity processing may include: on the substrate base formed with the aforementioned patterns, performing the conductorization treatment on the second electrode plate 62 and the active layer exposed by the first active via V1 and the second active via V2, to form the second electrode plate 62 conductorized, forming conductorized regions 12' at two sides of the first active layer 12, the second active layer 22, and the third active layer 32, the conductorized regions 12' serve as the source connection region and the drain connection region of the first active layer 12, the source connection region and the drain connection region of the second active layer 22, and the source connection region and the drain connection region of the third active layer 32, respectively, as shown in FIG. 21.

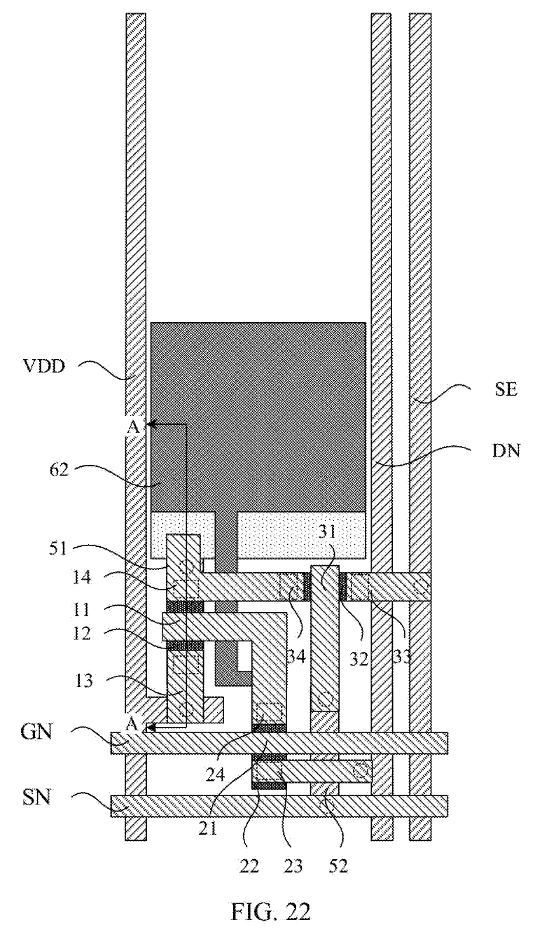

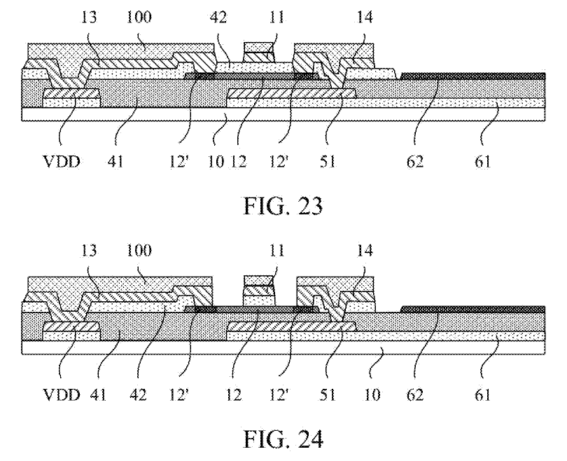

(25) A pattern of a second metal layer is formed. In an exemplary implementation, forming of the pattern of the second metal layer may include: depositing a second metal thin film on the substrate base formed with the aforementioned patterns, coating a layer of photoresist on the second metal thin film, forming a pattern of the photoresist by masking, exposure and development, and etching the second metal thin film by a first etching process, to form the pattern of the second metal layer and retain the photoresist 100 on the second metal layer. The pattern of the second metal layer includes at least a first scan line GN, a second scan line SN, a first gate electrode 11, a second gate electrode 21, a third gate electrode 31, a first source electrode 13, a first drain electrode 14, a second source electrode 23, a second drain electrode 24, a third source electrode 33, and a third drain electrode 34, as shown in FIG. 22 and FIG. 23. FIG. 23 is a sectional view in an A-A direction in FIG. 22.

In the exemplary implementation, the first scan line GN and the second scan line SN are parallel to each other, extend in the horizontal direction, and are both disposed at the lower side of the sub-pixel. The first scan line GN may be a switch scan line configured to provide the second gate electrode of the second transistor with an on/off signal for controlling the second transistor, the second scan line SN may be a compensation scan line configured to provide the third gate electrode of the third transistor with an on/off signal for controlling the third transistor, and the second scan line SN is connected with the second connection electrode 52 through the fourth via K4.

In an exemplary implementation, the first gate electrode 11 and the second drain electrode 24 are connected with each other as an integral structure, the second gate electrode 21 is connected with the first scan line GN as an integral structure, the third gate electrode 31 is connected with the second connection electrode 52 through the third via K3. Since the second connection electrode 52 is connected with the second scan line SN through the fourth via K4, the third gate electrode 31 is connected with the second scan line SN through the second connection electrode 52.

In an exemplary implementation, a first end of the first source electrode 13 is connected with the first power supply line VDD through the second via K2, and a second end of the first source electrode 13 is connected with the source connection region of the first active layer 12 through the second active via V2, to form the first source electrode 13 connected with the first power supply line VDD. A first end of the first drain electrode 14 is connected with the drain connection region of the first active layer 12 through the first active via V1, and is connected with the first connection electrode 51 through the first via K1, to achieve the connection of the first drain electrode 14 with the first electrode plate 61, and a second end of the first drain electrode 14 is connected with the third active layer 32 through the first active via V1, to form the first drain electrode 14 and the third drain electrode 34 in an integral structure.

In an exemplary implementation, a first end of the second source electrode 23 is connected with the data line DN through the fifth via K5, and the second end of the second source electrode 23 is connected with the source connection region of the second active layer 22 through the second active via V2, to form the second source electrode 23 connected with the data line DN. A first end of the second drain electrode 24 is connected with the drain connection region of the second active layer 22 through the first active via V1, and a second end of the second drain electrode 24 is erected on the channel region of the second active layer 22 on which no conductorization treatment is performed, to form the second drain electrode 24 and the first gate electrode 11 in an integral structure, and achieve the connection of the second drain electrode 24 with the second electrode plate 62.

In an exemplary implementation, a first end of the third source electrode 33 is connected with the compensation line SE through the sixth via K6, and a second end of the third source electrode 33 is connected with the source connection region of the third active layer 32 through the second active via V2, to form the third source electrode 33 connected with the compensation line SE. The third drain electrode 34 is connected with the drain connection region of the third active layer 32 through the first active via V1, and is connected with the first drain electrode 14 as an integral structure.

In an exemplary implementation, the first gate electrode 11, the first active layer 12, the first source electrode 13 and the first drain electrode 14 constitute a first transistor T1. The second gate electrode 21, the second active layer 22, the second source electrode 23, and the second drain electrode 24 constitute a second transistor T2. The third gate electrode 31, the third active layer 32, the third source electrode 33, and the third drain electrode 34 constitute a second transistor T2. The first electrode plate 61 and the conductorized second electrode plate 62 constitute a storage capacitor with a transparent structure.

(26) A second etching treatment is performed. In an exemplary implementation, the second etching process may include: etching the second insulating layer 42 downward by the second etching process in self-alignment using the pattern of the second metal layer and the photoresist 100 remaining on the second metal layer as a mask, to remove the second insulating layer 42 not covered by the pattern of the second metal layer on the first active layer 12, the second active layer 22, and the third active layer 32, as shown in FIG. 24.

In an exemplary implementation, side surfaces of the first source electrode 13 and the first drain electrode 14 facing the first gate electrode 11 are partially removed by proper amount of over-etching treatment, so that not only the side surfaces of the first source electrode 13 and the first drain electrode 14 facing the first gate electrode 11 are flush, but also a part of the conductorization region 12' in the first active via and a part of the conductorization region 12' in the second active via are exposed.

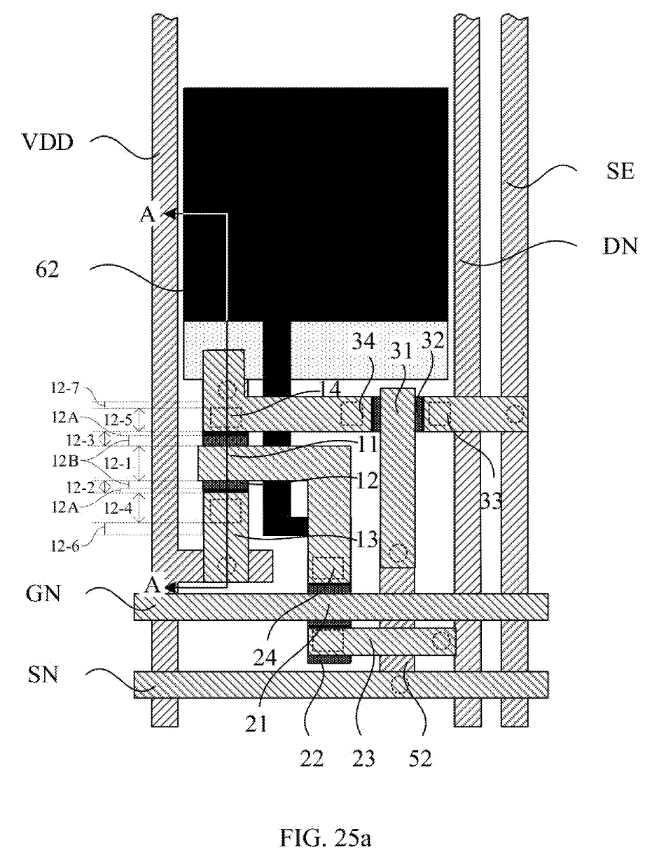

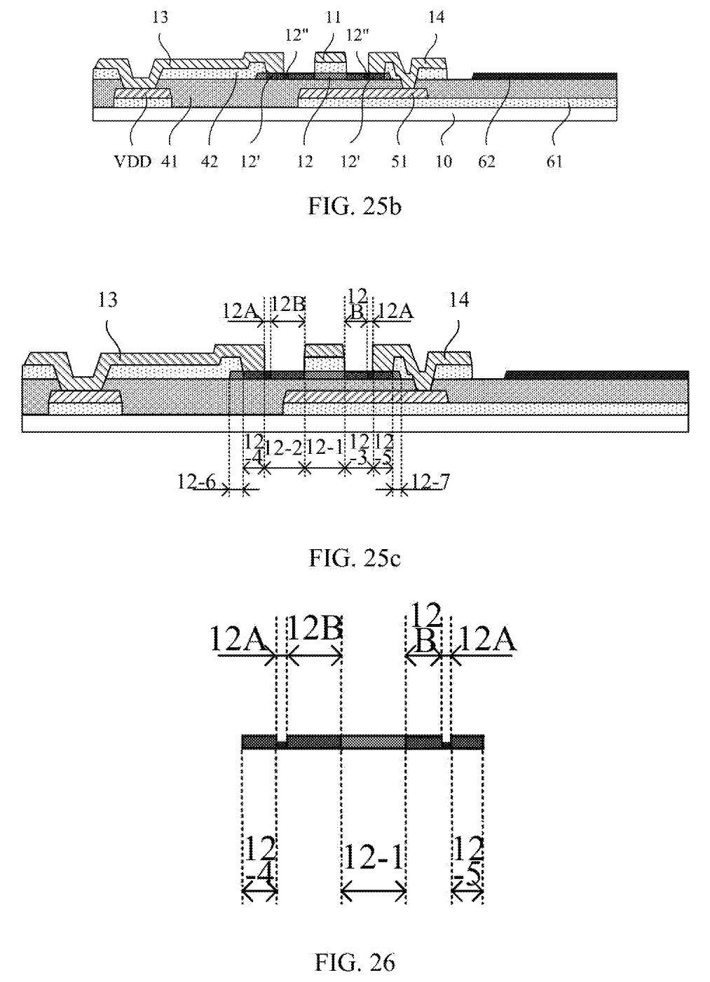

(27) A second conductorization treatment is performed. In an exemplary implementation, the second conductorization treatment may include: performing the second conductorization treatment on the first active layer 12, the second active layer 22, and the third active layer 32 using the second insulating layer 42, the pattern of the second metal layer disposed on the second insulating layer 42 and the photoresist 100 remaining on the second metal layer as masks, while performing the second conductorization treatment on the second electrode plate 62, to form a channel of a corresponding active layer and the second electrode plate 62 on which the second conductorization is performed, and stripping off the remaining photoresist, as shown in FIG. 25a, FIG. 25b, and FIG. 25c. FIG. 25b and FIG. 25c are sectional views in an A-A direction in FIG. 25a. Since the second conductorization treatment is a conductorization treatment of self-alignment using the second insulating layer 42, the pattern of the second metal layer, and the photoresist 100 as masks, a resulting channel width is substantially the same as widths of the first gate electrode 11, the second gate electrode 21, and the third gate electrode 31. The orthographic projection of the channel region of the first active layer 12 on the substrate base overlaps with the orthographic projection of the first connection electrode 51 on the substrate base, so that the first connection electrode 51 shields the channel region of the first active layer 12. The exemplary embodiment of the present disclosure greatly improves the alignment accuracy between the gate electrode and the lower channel and greatly improves the electrical characteristics of the thin film transistor through the conductorization treatment of self-alignment.

In an exemplary implementation, two conductorization treatments are performed on the first active layer, so that the first active layer forms four regions: a channel region 12-1 located in the middle, a source transition region 12-2 and a drain transition region 12-3 located at two sides of the channel region 12-1, a source connection region 12-4 located at a side of the source transition region 12-2 away from the channel region 12-1 and a drain connection region 12-5 located at a side of the drain transition region 12-3 away from the channel region 12-1, and a source outside region 12-6 located at a side of the source connection region 12-4 away from the channel region 12-1 and a drain outside region 12-7 located at a side of the drain connection region 12-5 away from the channel region 12-1. A boundary of an orthographic projection of the channel region 12-1 on the substrate base substantially overlaps with a boundary of an orthographic projection of the first gate electrode 11 on the substrate base. The source connection region 12-4 is connected with the first source electrode 13, the drain connection region 12-5 is connected with the first drain electrode 14. The source transition region 12-2 is located between the channel region 12-1 and the source connection region 12-4, i.e. located in a region between the first gate electrode 11 and the first source electrode 13, and the drain transition region 12-3 is located between the channel region 12-1 and the drain connection region 12-5, i.e. located in a region between the first gate electrode 11 and the first drain electrode 14. Similarly, the second active layer and the third active layer also form four regions. Since the two conductorization treatments are adopted, the region on which the first conductorization treatment is performed overlaps with the region on which the second conductorization treatment (as shown by the black region 12'' in FIG. 25b), so that both the source transition region 12-2 and the drain transition region 12-3 contain the first region 12A on which the two conductorization treatments are performed and the second region 12B on which only the second conductorization treatment is performed. Two helium (He) plasma treatments are performed on the first region 12A on which two conductorization treatments are performed, the oxygen content in the film layer is further reduced. The oxygen content of the first active layer corresponding to the first region 12A is less than the oxygen content of the first active layer corresponding to the second region 12B, which causes lower resistance and stronger conductivity. The conductivity of the first active layer corresponding to the first region 12A is higher than the conductivity of the first active layer corresponding to the second region 12B, which is beneficial to improve the electrical characteristics of the thin film transistor. Since only the first conductorization treatment is performed on the source connection region and the drain connection region, the conductivity of the first active layer corresponding to the first region 12A is higher than the conductivity of the first active layer corresponding to the source connection region and the drain connection region, and the oxygen content of the first active layer corresponding to the first region 12A is less than the oxygen content of the first active layer corresponding to the source connection region and the drain connection region. Since two conductorization treatments are performed on the second electrode plate 62, the conductibility of the second electrode plate 62 is improved, which is beneficial to improve the driving characteristics of the pixel driving circuit. In an exemplary implementation, the conductivity of the metal oxide layer corresponding to the second electrode plate 62 is higher than the conductivity of the first active layer corresponding to the second region 12B, or the oxygen content of the metal oxide layer corresponding to the second electrode plate 62 is less than the oxygen content of the first active layer corresponding to the second region 12B.

In an exemplary implementation, the width of the first region 12A may be less than the width of the source connection region 12-4 or the width of the first region 12A may be less than the width of the drain connection region 12-5.

In an exemplary implementation, the width of the first region 12A may be less than the width of the second region 12B.

In an exemplary implementation, the width of the first region 12A may be less than the width of the channel region 12-1.

In an exemplary implementation, an orthographic projection of at least portion of the first region 12A in the source transition region 12-2 on the substrate base does not overlap with an orthographic projection of the first metal layer on the substrate base, or an orthographic projection of at least portion of the first region 12A in the drain transition region 12-3 on the substrate base does not overlap with the orthographic projection of the first metal layer on the substrate base.

In an exemplary implementation, the width of the first region 12A may be less than the width of the source outside region 12-6 or the width of the first region 12A may be less than the width of the drain outside region 12-7.

In an exemplary implementation, the width of the second region 12B may be greater than the width of the source outside region 12-6 or the width of the second region 12B may be greater than the width of the drain outside region 12-7.

In an exemplary implementation, the width of the source outside region 12-6 may be less than the width of the source connection region 12-4 or the width of the drain outside region 12-7 may be less than the width of the drain connection region 12-5.

During the two conductorization treatments of the exemplary embodiment of the present disclosure, two etching treatments are performed on the second insulating layer, over-etching of the etching process may etch away a part of the thickness of the first active layer 12, thus the thickness of the first active layer corresponding to the first region 12A becomes thinner. The thickness of the first active layer corresponding to the first region 12A is less than the thickness of the first active layer corresponding to the second region 12B, the thickness of the first active layer corresponding to the first region 12A is less than the thickness of the first active layer corresponding to the source connection region and the drain connection region, and the thickness of the first active layer corresponding to the first region 12A is less than the thickness of the first active layer corresponding to the channel region, which is beneficial to improve the conductorization effect. In an exemplary implementation, a thickness of the first active layer 12 corresponding to a partial region of the first region 12A may become zero i.e. a hollow structure is formed. In an exemplary implementation, the thickness of the metal oxide layer corresponding to the second electrode plate 62 is less than the thickness of the first active layer corresponding to the second region 12B.

The formation mode for subsequently forming patterns of the third insulating layer, the color filter layer, the planarization layer, the anode, the pixel define layer, the organic light emitting layer, the cathode, the encapsulating layer and the like may be the same as the aforementioned processes (8) to (13).

As shown in FIG. 19 to FIG. 25c, the display substrate formed by the aforementioned preparation process may include: a substrate base 10; a transparent first electrode plate 61 disposed on the substrate base 10; a transparent conductive thin film disposed on the substrate base 10 and a first metal layer disposed on the transparent conductive thin film, the first metal layer includes at least a first power supply line VDD and a first connection electrode 51 connected with the first electrode plate 61; a first insulating layer 41 covering the first electrode plate 61 and the first metal layer; a metal oxide layer disposed on the first insulating layer 41, the metal oxide layer includes at least a first active layer 12 and a second electrode plate 62 on which two conductorization treatments are performed, an orthographic projection of the second electrode plate 62 on the substrate base 10 overlaps with an orthographic projection of the first electrode plate 61 on the substrate base 10 to form a transparent storage capacitor; the first active layer 12 includes three regions: a channel region located in the middle, a source transition region and a drain transition region located at two sides of the channel region, and a source connection region located at a side of the source transition region away from the channel region and a drain connection region located at a side of the drain transition region away from the channel region; an orthographic projection of the channel region of the first active layer 12 on the substrate base 10 overlaps with an orthographic projection of the first connection electrode 51 on the substrate base 10; a second insulating layer 42 disposed on the first active layer 12, the second insulating layer 42 is disposed with a first via K1 and a second via K2, a first active via V1, and a second active via V2, the first via K1 exposes the first connection electrode 51, and the second via K2 exposes the first power supply line VDD, the first active via V1 exposes the drain connection region of the first active layer 12 on which the conductorization treatment is performed, and the second active via V2 exposes the source connection region of the first active layer 12 on which the conductorization treatment is performed; a first gate electrode 11, a first source electrode 13 and a first drain electrode 14 disposed on the second insulating layer 42, a boundary of an orthographic projection of the first gate electrode 11 on the substrate base is within a boundary range of an orthographic projection of the second insulating layer 42 on the substrate base, and a boundary of the orthographic projection of the channel region of the first active layer 12 on the substrate base is within the boundary range of the orthographic projection of the second insulating layer 42 on the substrate base; a first end of the first source electrode 13 is connected with the first power supply line VDD through the second via K2, and a second end of the first source electrode 13 is connected with the source connection region of the first active layer 12 through the second active via K2; the first drain electrode 14 is connected with the drain connection region of the first active layer 12 through the first active via V1, and is connected with the first connection electrode 51 through the first via K1; a third insulating layer 43 covering the aforementioned structure; a color filter layer 70 is disposed on the third insulating layer 43; a planarization layer 44 covering the aforementioned structure, the planarization layer 44 is disposed with a seventh via K7 exposing the first drain electrode 14; and an anode 81 disposed on the planarization layer 44, the anode 81 is connected with the first drain electrode 14 through the seventh via K7.

In an exemplary implementation, the display substrate may also include a pixel define layer, an organic light emitting layer, a cathode, and an encapsulation layer and the like.

In an exemplary implementation, the source transition region of the first active layer 12 is located between the first gate electrode 11 and the first source electrode 13, the drain transition region of the first active layer 12 is located between the first gate electrode 11 and the first drain electrode 14, and the second insulating layer 42 of the source transition region and the drain transition region is removed by self-alignment etching.

In an exemplary implementation, the source connection region and the drain connection region of the first active layer 12 are formed by a first conductorization treatment, and the channel region of the first active layer 12 is formed during a second conductorization treatment of self-alignment.

Exemplary embodiments of the present disclosure propose a solution for forming a pixel circuit layer of a display substrate by four patterning processes. The first conductive layer and the first metal layer are formed by the same patterning process, the gate electrode, the source electrode and the drain electrode are disposed in the same layer and formed by the same patterning process, which reduces the number of patterning processes, shortens the process time, reduces the process cost, has good process compatibility, high process realizability, strong practicability, is highly mass-produced, and has a good application prospect.

Exemplary embodiments of the present disclosure propose a solution of two conductorization treatments, the first conductorization treatment is performed before the formation of the second metal layer, a wider channel region is formed by the first conductorization treatment. The second conductorization treatment is performed after the formation of the second metal layer, the channel region and the gate electrode formed during the second conductorization treatment of self-alignment have higher alignment accuracy, which greatly improves the alignment accuracy between the gate electrode and the lower channel region and greatly improves the electrical characteristics of the thin film transistor.

An exemplary embodiment of the present disclosure also provides a preparation method for a display substrate. In an exemplary implementation, the preparation method for the display substrate may include the following acts.

In act S1, a first metal layer and a metal oxide layer are formed sequentially on a substrate base, the metal oxide layer includes a first active layer.

In act S2, a second insulating layer and a second metal layer are formed sequentially, and a channel region, a source transition region and a drain transition region located at two sides of the channel region, a source connection region located at a side of the source transition region away from the channel region and a drain connection region located at a side of the drain transition region away from the channel region are formed in the first active layer by performing two conductorization treatments; the second metal layer includes a first gate electrode, a first source electrode, and a first drain electrode, the source connection region is connected with the first source electrode, and the drain connection region is connected with the first drain electrode; the source transition region and the drain transition region each include a first region away from the channel region and a second region close to the channel region; a conductivity of the first active layer corresponding to the first region is higher than a conductivity of the first active layer corresponding to the second region, or, oxygen content of the first active layer corresponding to the first region is less than oxygen content of the first active layer corresponding to the second region, or a thickness of the first active layer corresponding to the first region is less than a thickness of the first active layer corresponding to the second region.

In an exemplary implementation, act S1 may include the followings.

A transparent first electrode plate and the first metal layer are formed on the substrate base, a transparent conductive thin film is disposed between the first metal layer and the substrate base; the first metal layer includes a first power supply line and a first connection electrode, the first connection electrode is connected with the first electrode plate.

A first insulating layer covering the first electrode plate and the first metal layer is formed.

The metal oxide layer is formed on the first insulating layer, the metal oxide layer includes the first active layer and a second electrode plate, an orthographic projection of the second electrode plate on the substrate base and an orthographic projection of the first electrode plate on the substrate base have an overlapping region, and an orthographic projection of the channel region of the first active layer on the substrate base and an orthographic projection of the first connection electrode on the substrate base have an overlapping region.

In an exemplary implementation, act S2 may include the followings.

A second insulating layer is formed on the first active layer, and a first via and a second via are formed on the first insulating layer; the second insulating layer covers a middle region of the first active layer; the first via and the second via respectively expose the first connection electrode and the first power supply line.

A first conductorization treatment is performed on the second electrode plate and two side regions of the first active layer not covered by the second insulating layer to form the second electrode plate conductorized, and the source connection region and the drain connection region are formed at two sides of the first active layer respectively.

A second metal layer is formed and a photoresist is retained on the second metal layer; the second metal layer includes the first gate electrode, the first source electrode and the first drain electrode; the first gate electrode is located in the middle region of the first active layer, the first drain electrode is erected on the drain connection region, and is connected with the first connection electrode through the first via; a first end of the first source electrode is connected with the first power supply line through the second via, and a second end of the first source electrode is erected on the source connection region.

The second insulating layer not covered by the second metal layer is etched with the second metal layer and the photoresist disposed on the second metal layer as masks.

A second conductorization treatment is performed on the second electrode plate and the first active layer not covered by the second insulating layer with the second insulating layer, the second metal layer disposed on the second insulating layer and the photoresist disposed on the second metal layer as masks, to form the channel region of the first active layer and the source transition region and the drain transition region located at two sides of the channel region, wherein a boundary of an orthographic projection of the first gate electrode on the substrate base is located within a boundary range of an orthographic projection of the second insulating layer on the substrate base, and a boundary of an orthographic projection of the channel region on the substrate base is located within the range boundary of the orthographic projection of the second insulating layer on the substrate base, and the source transition region and the drain transition region each include the first region away from the channel region and the second region close to the channel region; the conductivity of the first active layer corresponding to the first region is higher than the conductivity of the first active layer corresponding to the second region, or, the oxygen content of the first active layer corresponding to the first region is less than the oxygen content of the first active layer corresponding to the second region, or the thickness of the first active layer corresponding to the first region is less than the thickness of the first active layer corresponding to the second region.

In another exemplary implementation, act S2 may include the followings.

The second insulating layer covering the first active layer is formed, the second insulating layer is formed with a first via, a second via, a first active via and a second active via, the first via and the second via respectively expose the first connection electrode and the first power supply line, and the first active via and the second active via respectively expose partial regions at two sides of the first active layer.

A first conductorization treatment is performed on the second electrode plate and the first active layer exposed in the first active via and the second active via, to form the second electrode plate conductorized and the source connection region and the drain connection region of the first active layer.

The second metal layer is formed and a photoresist is retained on the second metal layer; the second metal layer includes the first gate electrode, the first source electrode and the first drain electrode; the first gate electrode is located in a middle region of the active layer, the first drain electrode is connected with the drain connection region through the second active via, and is connected with the first connection electrode through the first via; a first end of the first source electrode is connected with the first power supply line through the second via, and a second end of the first source electrode is connected with the source connection region through the first active via.

The second insulating layer not covered by the second metal layer is etched with the second metal layer and the photoresist disposed on the second metal layer as masks.

A second conductorization treatment is performed on the second electrode plate and the first active layer not covered by the second insulating layer with the second insulating layer, the second metal layer disposed on the second insulating layer and the photoresist disposed on the second metal layer as masks, to form the channel region of the first active layer and the source transition region and the drain transition region located at two sides of the channel region, a boundary of an orthographic projection of the first gate electrode on the substrate base is located within a boundary range of an orthographic projection of the second insulating layer on the substrate base, and a boundary of an orthographic projection of the channel region on the substrate base is located within the range boundary of the orthographic projection of the second insulating layer on the substrate base, and the source transition region and the drain transition region each include the first region away from the channel region and the second region close to the channel region; the conductivity of the first active layer corresponding to the first region is higher than the conductivity of the first active layer corresponding to the second region, or, the oxygen content of the first active layer corresponding to the first region is less than the oxygen content of the first active layer corresponding to the second region, or the thickness of the first active layer corresponding to the first region is less than the thickness of the first active layer corresponding to the second region.

In an exemplary implementation, etching of the second insulating layer not covered by the second metal layer includes: removing, by self-alignment etching, the second insulating layer between the first gate electrode and the first source electrode and the second insulating layer between the first gate electrode and the first drain electrode.

Exemplary embodiments of the present disclosure provide a display substrate, a preparation method therefor, and a display apparatus. A gate electrode, a source electrode and a drain electrode are disposed in the same layer and formed by the same patterning process, only four patterning processes are required, which greatly reduces the number of patterning processes. Through two conductorization treatments, the alignment accuracy between the gate electrode and the lower channel region is greatly improved, and the electrical characteristics of the thin film transistor are greatly improved. The preparation method for the display substrate of the embodiment of the present disclosure reduces the number of patterning processes, shortens the process time, reduces the process cost, has good process compatibility, high process realizability, strong practicability, is highly mass-produced, and has a good application prospect.

The preparation process for the display substrate has been described in detail in the previous embodiments and will not be repeated here.

The present disclosure further provides a display apparatus, which includes the aforementioned display substrate. The display apparatus may be any product or component with a display function such as a mobile phone, a tablet computer, a television, a display, a laptop computer, a digital photo frame, a navigator, etc.

Although the implementations disclosed in the present disclosure are as above, the described contents are only implementations used for convenience of understanding the present disclosure and are not intended to limit the present disclosure. Any skill in the art to which the present disclosure pertains, without departing from the spirit and scope disclosed in the present disclosure, may make any modifications and changes in the form and details of the implementation. However, the scope of patent protection of the present application should still be subject to the scope defined by the appended claims.

1. A display substrate comprising a first metal layer, a first insulating layer, a metal oxide layer, a second insulating layer and a second metal layer which are stacked on a substrate base; wherein
the metal oxide layer comprises a first active layer, and the second metal layer comprises a first gate electrode, a first source electrode, and a first drain electrode;
the first active layer comprises a channel region, a source transition region and a drain transition region located at two sides of the channel region, a source connection region located at a side of the source transition region away from the channel region and a drain connection region located at a side of the drain transition region away from the channel region;
the source connection region is connected with the first source electrode, and the drain connection region is connected with the first drain electrode;
the source transition region and the drain transition region each comprise a first region away from the channel region and a second region close to the channel region; and
a thickness of the first active layer corresponding to the first region is less than a thickness of the first active layer corresponding to the second region, a distance from a boundary of the first region close to the source connection region to a boundary of the first region close to the second region is less than a distance from a boundary of the second region close to the first region to a boundary of the second region close to the channel region.

2. The display substrate according to claim 1, wherein the thickness of the first active layer corresponding to the first region is less than a thickness of the first active layer corresponding to the source connection region and the drain connection region.

3. The display substrate according to claim 1, wherein the distance from the boundary of the first region close to the source connection region to the boundary of the first region close to the second region is less than a width of the first active layer corresponding to the source connection region and a width of the first active layer corresponding to the drain connection region.

4. The display substrate according to claim 1, wherein
the display substrate comprises a plurality of sub-pixels arranged regularly,
each sub-pixel comprises a pixel driving circuit and an organic electroluminescent diode electrically connected with the pixel driving circuit,
the pixel driving circuit comprises a storage capacitor comprising a first electrode plate and a second electrode plate, and
an orthographic projection of the first electrode plate on the substrate base and an orthographic projection of the second electrode plate on the substrate base have an overlapping region.

5. The display substrate according to claim 4, wherein
the pixel driving circuit further comprises a first transistor, a second transistor, and a third transistor;
a gate electrode of the first transistor is coupled to a second electrode of the second transistor, a first electrode of the first transistor is coupled to a first power supply line, a second electrode of the first transistor is coupled to a first electrode of the organic electroluminescent diode, and a second electrode of the organic electroluminescent diode is coupled to a second power supply line;
a first electrode of the second transistor is coupled to a data line, a first electrode of the third transistor is coupled to a compensation line, and a second electrode of the third transistor is coupled to the second electrode of the first transistor; and
a first electrode of the storage capacitor is coupled to the gate electrode of the first transistor, and a second electrode of the storage capacitor is coupled to the second electrode of the first transistor.

6. The display substrate according to claim 4, wherein the first metal layer comprises the first electrode plate of the storage capacitor and the metal oxide layer comprises the second electrode plate of the storage capacitor.

7. The display substrate according to claim 4, wherein the second metal layer comprises the first electrode plate of the storage capacitor and the metal oxide layer comprises the second electrode plate of the storage capacitor.

8. The display substrate according to claim 4, wherein the first metal layer comprises the first electrode plate of the storage capacitor and the second metal layer comprises the second electrode plate of the storage capacitor.

9. The display substrate according to claim 1, wherein
the first metal layer comprises a first connection electrode, and
an orthographic projection of the channel region of the first active layer on the substrate base overlaps with an orthographic projection of the first connection electrode on the substrate base, so that the first connection electrode shields the channel region of the first active layer.

10. The display substrate according to claim 1, wherein
the first metal layer comprises a first power supply line and a first connection electrode;
the first source electrode and the first drain electrode are disposed on the first insulating layer;
the first drain electrode is erected on the drain connection region of the first active layer and is connected with the first connection electrode through a first via; and
a first end of the first source electrode is connected with the first power supply line through a second via, and a second end of the first source electrode is erected on the source connection region of the first active layer.

11. The display substrate according to claim 1, wherein
the first metal layer comprises a first power supply line and a first connection electrode;
the first source electrode and the first drain electrode are disposed on the second insulating layer;
the first drain electrode is connected with the drain connection region of the first active layer through a first active via and is connected with the first connection electrode through a first via; and
a first end of the first source electrode is connected with the first power supply line through a second via, and a second end of the first source electrode is connected with the source connection region of the first active layer through a second active via.

12. The display substrate according to claim 1, wherein
the second metal layer comprises a second gate electrode and a third gate electrode; and
an extending direction of the first gate electrode intersects an extending direction of the third gate electrode.

13. The display substrate according to claim 1, wherein
the second metal layer comprises a second gate electrode and a third gate electrode; and
an extending direction of the first gate electrode is perpendicular to an extending direction of the third gate electrode.

14. The display substrate according to claim 1, wherein
the second metal layer comprises a second gate electrode and a third gate electrode; and
a channel width of the channel region is the same as widths of the second gate electrode and the third gate electrode.

15. The display substrate according to claim 5, wherein
the second metal layer comprises a second gate electrode and a first scan line;
the first scan line extends in a direction parallel to the substrate base, and is disposed at a lower side of the plurality of sub-pixels; and
the first scan line is a switch scan line configured to provide the second gate electrode of the second transistor with an on/off signal for controlling the second transistor.

16. The display substrate according to claim 1, wherein
the second metal layer comprises a second gate electrode, a first scan line, and a second drain electrode, and
the second gate electrode is connected with the first scan line as an integral structure.

17. The display substrate according to claim 1, wherein
the second insulating layer located at a position where the first active layer is located covers a middle region of the first active layer, and has a covering width greater than a width of the channel region of the first active layer, and
two side regions of the first active layer not covered by the second insulating layer expose surfaces of the first active layer.

18. The display substrate according to claim 1, wherein
the first insulating layer comprises a first insulating thin film,
the second insulating layer comprises a second insulating thin film, and
a thickness of the second insulating thin film is less than a thickness of the first insulating thin film.

19. A display apparatus, comprising the display substrate of claim 1.
